(19) United States
(12) Patent Application Publication
(10) Pub. No.: US 2009/0235988 A1
(43) Pub. Date: Sep. 24, 2009

(54) SOLAR CELLS BASED ON POLYMER NANOWIRES

(75) Inventors: Samson A. Jenekhe, Seattle, WA (US); Hao Xin, Seattle, WA (US); Felix Sunjoo Kim, Seattle, WA (US)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: WASHINGTON, UNIVERSITY OF, Seattle, WA (US)

(21) Appl. No.: 12/409,354

(22) Filed: Mar. 23, 2009

Related U.S. Application Data
(60) Provisional application No. 61/038,683, filed on Mar. 21, 2008.

(51) Int. Cl. H01L 51/46; C08G 75/00; H01B 1/12; H01B 1/24; H01L 51/48

(52) U.S. Cl. 136/263; 528/380; 252/500; 252/511; 438/82; 977/762; 257/E21.09; 257/E51.014; 257/E51.029; 977/948

(57) ABSTRACT

Solar cells having active layers that include poly(3-alkylthiophene) nanowires.

### CROSS-REFERENCE TO RELATED APPLICATION

This application claims the benefit of U.S. Provisional Patent Application No. 61/038,683, filed Mar. 21, 2008, expressly incorporated herein by reference in its entirety.

### STATEMENT OF GOVERNMENT LICENSE RIGHTS

This invention was made with Government support under Grant No. DE-FG02-07ER46467 awarded by the Department of Energy and Grant Nos. CTS-0437912 and DMR-0120967 awarded by the National Science Foundation. The Government has certain rights in the invention.

### BACKGROUND OF THE INVENTION

The excitonic nature of photovoltaic cells based on organic or polymer semiconductors poses major challenges in developing them as practical, low-cost, power sources derived from the sun. The improved exciton dissociation accompanying the gradual evolution of the polymer solar cell architecture from the Schottky barrier single-layer to the donor/acceptor bilayer heterojunction and to the donor/acceptor bulk heterojunction (BHJ) has seen the power conversion efficiency of devices rise from about 0.1% to 1-1.5% and to 3-5%, respectively. The BHJ polymer solar cell, consisting of a binary blend or composite of a donor polymer and an acceptor material, such as fullerene, CdSe nanocrystals, TiO₂ nanoparticles, carbon nanotubes, an n-type polymer, or n-type small molecule, was introduced in 1995 to address the problem of small exciton diffusion lengths (L_{d}=5-20 nm) in current organic/polymer semiconductors. Optimized BHJ photovoltaic devices based on regioregular poly(3-hexylthiophene) (P3HT) and the [60]fullerene, [6,6]-phenyl-C₆₁-butyric acid methyl ester (PC₆₁BM) now have power conversion efficiencies of up to 4-5%.

One of the difficult challenges in improving the performance of BHJ polymer solar cells is that the ideal two-phase, nanoscale, bicontinuous donor/acceptor morphology remains elusive because the thermodynamics and kinetics of blend phase separation cannot be controlled since numerous variables are involved. The time-dependent Ostwald ripening or domain coarsening phenomena in phase-separated polymer blends are also major sources of instability and poor durability of current BHJ polymer solar cells.

Despite the advances in the development of semiconducting polymers and related materials for use in photovoltaic devices, a need exists for materials and materials processing that improve the performance of these devices. The present invention seeks to fulfill this need and provides further related advantages.

### SUMMARY OF THE INVENTION

The present invention provides poly(3-alkylthiophene) nanowires useful as donors in bulk heterojunction layers of photovoltaic devices (e.g., solar cells). The invention also provides composites, photovoltaic cells, and field-effect transistors that include the nanowires.

In one aspect, the invention provides composite that includes poly(3-alkylthiophene) nanowires. In one embodiment, the composite includes one or more poly(3-alkylthiophene) nanowires and one or more bulk heterojunction solar cell acceptor compounds. In this embodiment, the poly(3-alkylthiophene) nanowires serve as the donor compound in the bulk heterojunction layer of the solar cell. Suitable poly(3-alkylthiophene) nanowires useful in the composites of the invention include poly(3-methylthiophene), poly(3-ethylthiophene), poly(3-propylthiophene), poly(3-butylthiophene), poly(3-pentylthiophene), poly(3-hexylthiophene), poly(3-heptylthiophene), poly(3-octylthiophene), poly(3-nonylthiophene), poly(3-decylthiophene) nanowires, and mixtures thereof. The poly(3-alkylthiophene) nanowires can include mixtures of poly(3-alkylthiophene)s. Suitable acceptor compounds include fullerenes and fullerene derivatives, inorganic nanocrystals, and semiconducting nanoparticles.

In another aspect, the invention provides methods for making poly(3-alkylthiophene) nanowire composites. In one embodiment, the method includes depositing a mixture of one or more poly(3-alkylthiophene) nanowires and one or more bulk heterojunction solar cell acceptor compounds onto a substrate to provide a composite.

In the method, the nanowire can be formed and then combined with the acceptor compound and deposited onto the substrate, or the nanowire can be formed from a solution of the poly(3-alkylthiophene) and the acceptor compound and that combination deposited onto the substrate. In one embodiment, the mixture of the one or more acceptor compounds and the one or more nanowires is prepared by combining a first solution comprising the one or more acceptor compounds in a first solvent with a suspension of the one or more nanowires in a second solvent. In another embodiment, the mixture of the one or more acceptor compounds and the one or more nanowires is prepared by combining a first solution comprising the one or more acceptor compounds in a first solvent with second solution comprising one or more poly(3-alkylthiophene)s in a second solvent.

The mixture of poly(3-alkylthiophene) nanowires and acceptor compound can be deposited onto a substrate by spin coating, drop coating, blade coating, spray coating, or screen printing the mixture.

In one embodiment, the method further includes thermal annealing of the composite.

In other aspects of the invention, photovoltaic devices and methods for making and using the devices are provided.

In one embodiment, the photovoltaic device includes a hole-collecting electrode, an electron-collecting electrode, and a photovoltaic layer intermediate the electrodes. The photovoltaic layer includes a composite (e.g., film) of the invention that includes one or more poly(3-alkylthiophene) nanowires and one or more bulk heterojunction solar cell acceptor compounds. The devices can further include an electron-transporting or hole-blocking layer intermediate the photovoltaic layer and the electron-collecting electrode, and/or a hole-transporting layer intermediate the photovoltaic layer and the hole-collecting electrode. The devices can further include a substrate that abuts either the electron-collecting electrode or the hole-collecting electrode.

In another aspect, the invention provides a method for making a photovoltaic device. In one embodiment, the method includes forming a photovoltaic layer on a hole-collecting electrode, and then forming an electron-collecting electrode on the photovoltaic layer. In another embodiment, the method includes forming a photovoltaic layer on an electron-collecting electrode, and then forming a hole-collecting electrode on the photovoltaic layer. In the methods, forming the photovoltaic layer includes spin coating, drop coating, blade coating, spray coating, or screen printing a composition of the invention.

In a further aspect of the invention, a method for generating an electrical current is provided. In the method, the photovoltaic layer of a photovoltaic device of the invention is exposed to electromagnetic radiation of a wavelength sufficient to generate electrons and holes in the photovoltaic layer.

In another aspect, the invention provides a poly(3-pentylthiophene) nanowire. Representative nanowires have lengths of from about 100 to about 50,000 nm, and widths of from about 5 to about 100 nm.

### DESCRIPTION OF THE DRAWINGS

The foregoing aspects and many of the attendant advantages of this invention will become more readily appreciated as the same become better understood by reference to the following detailed description, when taken in conjunction with the accompanying drawings.

FIG. 1A is a schematic illustration of a representative method for making a composite of the invention by combining representative pre-assembled nanowires with a bulk heterojunction acceptor compound in solution and then depositing the combination on a substrate to provide the composite.

FIG. 1B is a schematic illustration of a representative method for making a composite of the invention by combining a nanowire-forming organic semiconducting polymer and a bulk heterojunction acceptor compound in solution to provide a combination of in situ self-assembled nanowires in a solution containing the acceptor compound, and then depositing the combination on a substrate to provide the composite.

FIG. 1C illustrates the chemical structures of a representative poly(alkylthiophene) (P3BT) and a representative bulk heterojunction acceptor compound (PC₆₁BM) useful in making the composite of the invention.

FIG. 1D are UV-Vis absorption spectra of (1) P3BT solution in ODCB; (2) P3BT-nw suspension in ODCB; (3) P3BT:C₆₁-PCBM blend on ITO/PEDOT substrate; and (4) P3BT-nw/C₆₁-PCBM nanocomposite on ITO/PEDOT substrate.

FIG. 2A is a TEM image of a representative P3BT-nw/C₆₁-PCBM (1/1 wt. ratio) composite of the invention.

FIG. 2B is an AFM image of a representative P3BT-nw/C₆₁-PCBM (1/1 wt. ratio) composite of the invention.

FIGS. 3A and 3B are current-voltage curves of representative solar cells of the invention having different active layer films: (3A) P3BT-nw/C₆₁-PCBM nanocomposite (1/1) (70 nm) (▪) and P3BT:C₆₁-PCBM blend (1:1) (80 nm) (▴); (3B) P3BT-nw/C₇₁-PCBM composite (1/0.75) (90 nm) (▪), P3HT:C₇₁-PCBM (1:1) blend (120 nm) (▴). The films in (3A) were dried in a vacuum oven at 60° C. overnight and films in (3B) were annealed in a glove box at 110° C. for 10 min.

FIGS. 4A and 4B are tapping mode AFM topography (4A) and phase (4B) images of P3BT nanowires spin-coated onto a silicon wafer substrate.

FIGS. 5A-5D are tapping mode AFM topography (5A, 5C) and phase (5B, 5D) images of representative films of the invention, P3BT-nw/C₆₁-PCBM (1/1) nanocomposite films (5A, 5B) and P3BT:C₆₁-PCBM (1:1) blend film (5C, 5D), spin-coated onto ITO/PEDOT substrates.

FIG. 6 are UV-Vis absorption spectra of representative films of the invention, P3BT-nw/C₆₁-PCBM (1:1, 70 nm) and P3BT-nw/C₇₁-PCBM (1:0.75, 90 nm), on ITO/PEDOT substrate. The P3BT-nw/C₆₁-PCBM film was spin-coated in air and dried in a 60° C. oven under vacuum and the P3BT-nw/C7₁-PCBM film was spin-coated and annealed in a glove box at 110° C. for 5 min.

FIG. 7 is a current-voltage curve comparing representative solar cells of the invention, P3BT-nw/C₇₁-PCBM composite solar cells with different compositions: P3BT-nw/C₇₁-PCBM 1:1 and P3BT-nw/C₇₁-PCBM 1:0.75. The films were spin-coated and annealed in a glove box at 110° C. for 10 min.

FIGS. 8A and 8B are output (8A) and transfer (8B) curves for a representative P3BT-nw/C₆₁-PCBM (1/1) nanocomposite thin-film transistor.

FIGS. 9A and 9B are bright field TEM images of blend films with P3BT:PC₆₁BM compositions of 1:2 and 1:0.25, respectively (scale bar is 500).

FIGS. 10A-10H are tapping mode AFM topography (10A, 10C, 10E, 10G) and phase (10B, 10D, 10F, 10H) images of representative films of the invention, P3BT:PC₆₁BM blend films with different compositions: 1:2 (10A and 10B), 1:1 (10C and 10D), 1:0.5 (10E and 10F), and 1:0.25 (10G and 10H). The area is 5 μm×5 μm for all the images. The films were spin-coated onto ITO/PEDOT substrates and annealed at 130° C. for 10 min.

FIG. 11A compares UV-Vis absorption spectra of P3BT nanowire suspension in ODCB and as a spin-coated film on glass; FIG. 11B compares normalized absorption spectra of P3BT-nw and P3BT-nw:PC₆₁BM blend films of different compositions. All the films were annealed at 130° C. for 10 min. P3BT-nw film was spin-coated on a glass slide whereas P3BT-nw:PC₆₁BM blend films were spin-coated on top of ITO/PEDOT substrates.

FIG. 12A compares experimental dark-current density-voltage curves for P3BT-nw:PC₆₁BM hole only devices as a function of blend composition (wt.% of P3BT). The solid lines represent the fit using a model of single carrier SCL current with field-dependent mobility; FIG. 12B compares the SCLC and field-effect hole motilities of P3BT-nw:PC₆₁BM nanocomposites versus composition (wt.% of P3BT).

FIG. 13A compares current-voltage characteristics of P3BT-nw:PC₆₁BM blend solar cells with a structure of ITO/PEDOT/P3BT:PC₆₁BM/LiF/Al at different blend ratios, measured under AM1.5 white light illumination at 100 mW/cm². Inset: schematic structure of the solar cell device; FIG. 13B compares current-voltage curves of P3BT-nw:PC₆₁BM in (a) and their dark curves plotted in semilogarithmic format; FIG. 13C compares current-voltage curves of the P3BT:PC₆₁BM (1:0.5 wt:wt) blend device in the dark and under 100 mW/cm² illumination.

FIG. 14A compares current density-voltage characteristics of P3BT:PC₆₁BM (1:0.5) blend solar cell in the dark and under AM1.5 white light illumination at different light intensities; FIG. 14B compares the current density of the P3BT:PC₆₁BT solar cells as a function of the light intensity.

FIGS. 15A-15D illustrate the dependence of the short-circuit density J_{SC} (15A), the open circuit voltage V_{OC} (15B), the fill factor FF (15C), and the power conversion efficiency PCE (15D) of P3BT:PC₆₁BM blend solar cells on blend composition (wt % P3BT). All measurements were done under AM1.5 white light illumination at 100 mW/cm².

FIGS. 16A-16D are tapping mode AFM phase images of P3BT-nw films prepared under different conditions: (16A) 3 min aging and annealing; (16B) 50 min aging and annealing; (16C) 100 min aging and annealing; and (16D) 100 min aging, no annealing. The films were spin-casted on top of ITO/PEDOT substrates. The annealing temperature and time were 150±10° C. and 10, respectively. The dimension is 5×5 μm and the scale is 30 degree for all the images.

FIGS. 17A and 17B are bright-field TEM images of P3BT-nw thin films: 17A film was annealed at 170±10° C. for 10 min after 3 min aging; 17B film was dried under vacuum at room temperature after 100 min aging. The insets are the electron diffraction of the corresponding film.

FIG. 18 compares experimental dark-current density-voltage curves of P3BT-nw hole-only devices under film processing conditions same as those in FIG. 16. The solid lines represent the fit using a model of single carrier space charge limited current (SCLC) with field-dependent mobility; zero-field SCLC and OFET hole motilities of P3BT-nw films as a function of the film processing conditions.

FIGS. 19A-19D are tapping mode AFM phase images of P3BT-nw/PC₇₁BM (1:1) nanocomposites films prepared under different conditions: (19A) 3 min aging and annealing; (19B) 40 min aging and annealing; (19C) 100 min aging and annealing; and (19D) 100 min aging, no annealing. The films were spin-casted on top of ITO/PEDOT substrates. The annealing temperature and time were 150±10° C. and 10 min, respectively. The dimension of the images is 5×5 μm.

FIGS. 20A and 20B are bright-field TEM images of P3BT-nw/PC₇₁BM (1:1) nanocomposite thin films spin-casted on top of ITO/PEDOT substrates and peeled off by putting the samples in water: (20A) film was annealed at 170° C. for 10 min after 3 min aging, same as that in FIG. 19A; (20B) film was dried under vacuum at room temperature after 100 min aging, same to that in FIG. 19D. The insets are the electron diffraction of the corresponding film.

FIGS. 21A and 21B are J-V curves for P3BT-nw:PC₇₁BM solar cells with a structure of ITO/PEDOT/P3BT-nw:PC₇₁BM/LiF/Al at blend ratio of 1:0.5 (21A) and 1:1 (21B). The curves were measured under AM1.5 white light illumination at 100 mW/cm².

FIGS. 22A and 22B are TEM images of poly(3-pentylthiophene) nanowires formed from ODCB solution.

FIG. 23 is a TEM image of P3PT nanowires formed from blends with fullerene (1:1 ratio) (i.e., in-situ formed nanowires).

FIG. 24 is a J-V curve for a photovoltaic cell of P3PT-nw:PC₇₁BM.

FIG. 25 is an AFM image of P3PT film spin-coated from a 2 mg/ml ODCB solution showing self-assembled nanowires in a thin film.

FIG. 26 is a J-V curve for a photovoltaic cell of P3PT:PC₇₁BM (1:1) (spin-coated active layer) (device structure: ITO/PEDOT/P3PT:PC₇₁BM (1:1)/LiF/Al).

FIGS. 27 and 28 are schematic illustrations of representative photovoltaic devices of the invention having a bulk heterojunction layer that includes a poly(3-alkylthiophene) nanowire.

### DETAILED DESCRIPTION OF THE INVENTION

The present invention provides poly(3-alkylthiophene) nanowires useful as donors in bulk heterojunction layers of photovoltaic devices (e.g., solar cells). The invention also provides composites, photovoltaic cells, and field-effect transistors that include the nanowires.

In one aspect, the invention provides composites that includes poly(3-alkylthiophene) nanowires. In one embodiment, the composite includes one or more poly(3-alkylthiophene) nanowires and one or more bulk heterojunction solar cell acceptor compounds. In this embodiment, the poly(3-alkylthiophene) nanowires serve as the donor compound in the bulk heterojunction layer of the solar cell.

As used herein, the term “one or more poly(3-alkylthiophene) nanowires” refers to a plurality of one or more types of poly(3-alkylthiophene) nanowires. The composite can include a single type of poly(3-alkylthiophene) nanowire (e.g., poly(3-butylthiophene) nanowires). Alternatively, the composite can include more than one type of poly(3-alkylthiophene) nanowire (e.g., a combination of two nanowires, such as a combination of poly(3-butylthiophene) nanowires and poly(3-pentylthiophene) nanowires). Nanowires prepared from a combination of one or more poly(3-alkylthiophene)s can also be used Suitable poly(3-alkylthiophene) nanowires include poly(3-methylthiophene), poly(3-ethylthiophene), poly(3-propylthiophene), poly(3-butylthiophene), poly(3-pentylthiophene), poly(3-hexylthiophene), poly(3-heptylthiophene), poly(3-octylthiophene), poly(3-nonylthiophene), and poly(3-decylthiophene) nanowires. Suitable poly(3-alkylthiophene) nanowires include poly(3-n-alkylthiophene) nanowires (e.g., poly(3-n-propylthiophene), poly(3-n-butylthiophene), poly(3-n-pentylthiophene), poly(3-n-hexylthiophene), poly(3-n-heptylthiophene), poly(3-n-octylthiophene), poly(3-n-nonylthiophene), and poly(3-n-decylthiophene)).

The poly(3-alkylthiophene) nanowires can be prepared by self-assembly from poly(3-alkylthiophene) solutions. Representative nanowires useful in composites and structures of the invention have lengths of from about 100 to about 50,000 nm, and widths of from about 5 to about 100 nm.

Poly(3-alkylthiophenes) useful in making the nanowires of the composites and structures of the invention include regioregular poly(3-alkylthiophenes) having 50-100% head-to-tail regioregularity. Suitable poly(3-alkylthiophenes) have an average molecular weight of from about 5,000 to about 500,000 g/mole. In one embodiment, the poly(3-alkylthiophene) has an average molecular weight of from about 30,000 to about 80,000 g/mole.

The composite of the invention also includes one or more bulk heterojunction solar cell acceptor compounds. As used herein, the term “one or more bulk heterojunction solar cell acceptor compounds” refers to one or more types of bulk heterojunction solar cell acceptor compounds. The composite can include a single type of acceptor compound (e.g., a fullerene). Alternatively, the composite can include more than one type of acceptor compound (e.g., a combination of two different fullerenes or a combination of a fullerene and a semiconducting nanoparticle).

Acceptor compounds suitable for use in bulk heterojunction layers in solar cells are known in the art. Suitable acceptor compounds include fullerenes and fullerene derivatives, inorganic nanocrystals, and semiconducting nanoparticles. Representative acceptor compounds include nanoparticles such as CdSe, CdS, TiO₂, and ZnO₂ nanoparticles; carbon nanotubes and derivatives; n-type polymers such as polybenzobisimidazobenzophenanthrolines and polyquinones; and n-type small molecules such as perylene tetracarboxydiimide and derivatives. Representative fullerene derivatives include [6,6]-phenyl-C₆₁ butyric acid methyl ester, [6,6]-phenyl-C₇₁ butyric acid methyl ester, and [6,6]-phenyl-C₈₅ butyric acid methyl ester.

In one embodiment, in addition to including one or more poly(3-alkylthiophene) nanowires, the composite includes one or more other donor compounds. Donor compounds suitable for use in bulk heterojunction layers in solar cells are known in the art.

The ratio of nanowire donor and acceptor compound in the composite should be set at a value that allows each to permit percolation sufficient for hole and electron extraction, and at the same time retain high light absorption efficiency. In the composite, the ratio of poly(3-alkylthiophene) nanowire to acceptor compound is from about 1:0.2 to about 1:5 (weight ratio). Above these ratios, the acceptor compound cannot form a percolation path for effective electron transport. Below these ratios, the composite's absorbance (due primarily to polymer nanowire) is too low to efficiently harvest incident light.

The composites of the invention can have a variety of forms. In one embodiment, the composite is a film (e.g., thin film). Films with thicknesses less than about 30 nm will generally have insufficient absorption and will have low photovoltaic efficiency. Films with thicknesses about 500 nm will generally have limited carrier mobility and lower charge collection efficiency. In one embodiment, the composite is a film having a thickness of from about 30 to about 500 nm. Such films are suitable as active layers in photovoltaic devices.

In another aspect, the invention provides methods for making poly(3-alkylthiophene) nanowire composites. In one embodiment, the method includes depositing a mixture of one or more poly(3-alkylthiophene) nanowires and one or more bulk heterojunction solar cell acceptor compounds onto a substrate to provide a composite.

In the method, the nanowire can be formed and then combined with the acceptor compound and deposited onto the substrate, or the nanowire can be formed from a solution of the poly(3-alkylthiophene) and the acceptor compound and that combination deposited onto the substrate. In one embodiment, the mixture of the one or more acceptor compounds and the one or more nanowires is prepared by combining a first solution comprising the one or more acceptor compounds in a first solvent with a suspension of the one or more nanowires in a second solvent. In another embodiment, the mixture of the one or more acceptor compounds and the one or more nanowires is prepared by combining a first solution comprising the one or more acceptor compounds in a first solvent with second solution comprising one or more poly(3-alkylthiophene)s in a second solvent. In these embodiments, first and second solvents are compatible with the deposition technique (e.g., spin coating). The first and second solvent can be the same, and, when different, must be miscible.

Suitable techniques for depositing the mixture of one or more poly(3-alkylthiophene) nanowires and one or more bulk heterojunction solar cell acceptor compounds onto a substrate include spin coating, drop coating, blade coating, spray coating, or screen printing.

In one embodiment, the amount of acceptor compound in the mixture is from about 5 to about 50 mg/mL. In one embodiment, the amount of nanowire in the mixture is from about 5 to about 50 mg/mL. In one embodiment, the ratio of acceptor compound to nanowires in the mixture is from about 0.2:1 to about 5:1 (weight ratio).

The preparation and characterization of poly(3-butylthiophene) (P3BT), P3BT nanowires, and composites, photovoltaic cells, and field-effect transistors that include the nanowires are described in Examples 1 and 2. Example 2 describes the use of in situ self-assembled nanowires (i.e., nanowires formed in the presence of acceptor compounds).

The method can further include thermal annealing the film. Thermal annealing can include heating at a temperature of from about 60 to about 240° C. for a time from about 1 to about 120 min. In one embodiment, thermal annealing includes heating at a temperature of from about 175° C. for about 10 min. As described below, thermal annealing can be used to modify the morphology of the nanowire/acceptor-containing film to advantageously affect film performance in a photovoltaic device.

The effect of thermal annealing on composites, photovoltaic cells, and field-effect transistors that include nanowires are described in Example 3.

In other aspects of the invention, photovoltaic devices and methods for making and using the devices are provided. The photovoltaic devices include a photovoltaic or (active) bulk heterojunction layer that includes poly(3-alkylthiophene) nanowires as described above.

In one embodiment, the photovoltaic device includes a hole-collecting electrode, an electron-collecting electrode, and a photovoltaic layer intermediate the electrodes. The photovoltaic layer includes a composite (e.g., film) of the invention that includes one or more poly(3-alkylthiophene) nanowires and one or more bulk heterojunction solar cell acceptor compounds, as described above.

Suitable hole-collecting electrodes include a material selected from a continuous metal, a metal grid, indium-tin oxide, and a conductive polymeric material. Suitable electron-collecting electrodes include a conductive metal.

The devices of the invention can further include an electron-transporting or hole-blocking layer intermediate the photovoltaic layer and the electron-collecting electrode. Suitable electron-transporting layers include a metal oxide. Representative metal oxides include zinc oxide and titanium oxide.

The devices of the invention can further include a hole-transporting layer intermediate the photovoltaic layer and the hole-collecting electrode.

The devices of the invention can further include a substrate. The substrate abuts either the electron-collecting electrode or the hole-collecting electrode.

Representative photovoltaic devices of the invention are described in Examples 1-4.

In another aspect, the invention provides a method for making a photovoltaic device. In one embodiment, the method includes forming a photovoltaic layer on a hole-collecting electrode, and then forming an electron-collecting electrode on the photovoltaic layer. In another embodiment, the method includes forming a photovoltaic layer on an electron-collecting electrode, and then forming a hole-collecting electrode on the photovoltaic layer. As noted above, the photovoltaic layer includes a composite of the invention.

In the methods, forming the photovoltaic layer includes spin coating, drop coating, blade coating, spray coating, or screen printing a composition of the invention.

In the methods, forming the electrode includes spin coating, drop coating, blade coating, spray coating, screen-printing, inkjet printing, or vapor depositing a composition that includes an electrode material.

In one embodiment, the methods further include forming a hole-transporting layer.

In another embodiment, the method further includes forming an electron-transporting layer.

In a further aspect of the invention, a method for generating an electrical current is provided. In the method, the photovoltaic layer of a photovoltaic device of the invention is exposed to electromagnetic radiation of a wavelength sufficient to generate electrons and holes in the photovoltaic layer. The effectiveness of representative photovoltaic devices of the invention to generate electrical current is described below and in Examples 1-4.

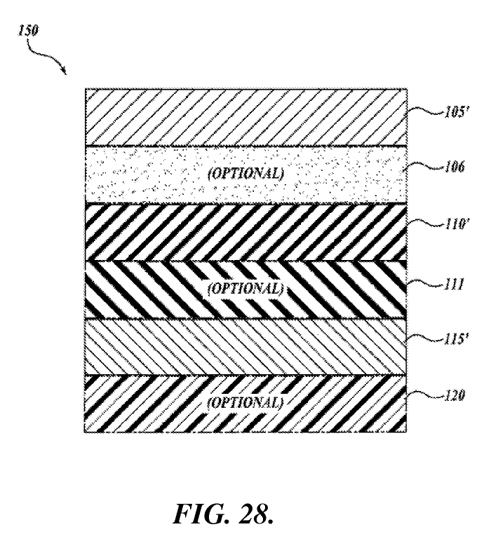

FIGS. 27 and 28 are schematic illustration of representative solar cells that advantageously incorporate the nanowires of the invention. In these devices, the nanowires are a component of the devices' photovoltaic layer.

Referring to FIG. 27, representative device 100 includes hole-collecting electrode 115, electron-collecting electrode 105, and photovoltaic layer 110.

Referring to FIG. 28, representative device 150, in addition to hole-collecting electrode 115′, electron-collecting electrode 105′, and photovoltaic layer 110′, device 150 includes optional layers 106 (electron-transporting layer), 111 (hole-transporting layer), and 120 (substrate).

In another aspect, the invention provides a poly(3-pentylthiophene) nanowire. As used herein, the term “poly(3-pentylthiophene) nanowire” refers to a nanowire made from and that includes poly(3-pentylthiophene). Representative nanowires have lengths of from about 100 to about 50,000 nm, and widths of from about 5 to about 100 nm.

The poly(3-pentylthiophene) is a regioregular poly(3-pentylthiophene) having 50-100% head-to-tail regioregularity. The poly(3-pentylthiophene) has an average molecular weight of from about 5,000 to about 500,000 g/mole. In one embodiment, the poly(3-pentyl thiophene has an average molecular weight of from about 30,000 to about 80,000 g/mol. In one embodiment, the poly(3-pentylthiophene) nanowire is a poly(3-n-pentylthiophene).

The poly(3-pentylthiophene) nanowire can be made by dissolving a poly(3-pentylthiophene) in a suitable solvent, usually with heating, to provide a poly(3-pentylthiophene) solution, and then cooling the solution to provide a suspension comprising poly(3-pentylthiophene) nanowires. The nanowires are formed by self-assembly from the poly(3-pentylthiophene) solution. Suitable solvents for preparing poly(3-alkylthiophene) nanowires include 1,2-dichlorobenzene, toluene, 1,4-dichlorobenzene, xylene, chlorobenzene, trichlorobenzene, cyclohexanone, anisole, dichloromethane, chloroform, hexane, and tetrahydrofuran, among others. In one embodiment, the solvent is 1,2-dichlorobenzene.

The preparation and characterization of poly(3-pentylthiophene) (P3PT), P3PT nanowires, and composites and photovoltaic cells that include the nanowires are described in Example 4.

The following is a description of representative poly(3-alkylthiophene) nanowires and composites and structures that include the nanowires.

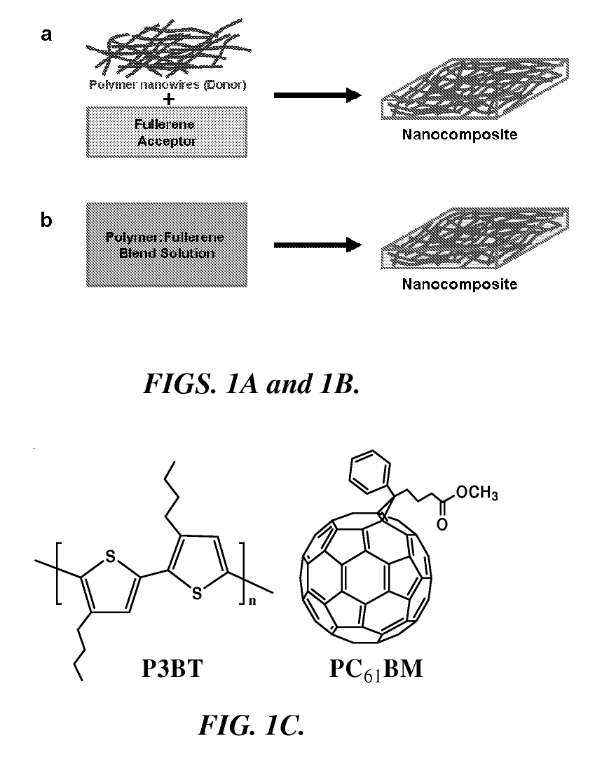

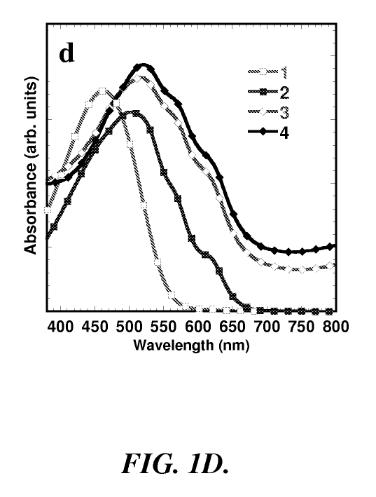

The present invention provides highly efficient polymer/fullerene (e.g., C₆₁-PCBM and C₇₁-PCBM) solar cells in which a 3-D network of pre-assembled polymer semiconductor nanowires serves as the donor component in a sea of fullerene acceptor (see FIG. 1A). In this approach, an electrically bicontinuous nanoscale morphology is realized without going through the difficult path of blend phase-separation phenomena. For example, photovoltaic cells with 3.0% power conversion efficiency (at 100 mW/cm², AM1.5, 10 mm² device area, in air) were achieved by using poly(3-butylthiophene) nanowires (P3BT-nw) as the donor and C₇₁-PCBM as the acceptor. P3HT:C₇₁-PCBM blend photovoltaic cells, prepared by the conventional annealing-induced phase separation and similarly tested, gave a 3.0% PCE. Thus, poly(3-butylthiophene) has been demonstrated to exhibit photovoltaic properties that are comparable to the much studied poly(3-hexylthiophene).

P3BT nanowires were prepared as dispersions by solution-phase self-assembly (see Example 1). Briefly, a heated solution (6 mg/mL) of P3BT in 1,2-dichlorobenzene (ODCB) was slowly cooled from 90-100° C. to room temperature in a dark environment, allowing P3BT nanowire self-assembly. The resulting P3BT-nw suspension is quite stable; the nanowires do not dissolve in the solvent by dilution and they do not settle or precipitate in over one month. The P3BT-nw/PCBM nanocomposites were prepared by mixing the nanowire suspension with fullerene solution whereas the P3BT:PCBM blends were made by mixing the hot P3BT solution with PCBM solution before spin-coating (see Example 1). FIGURE ID shows the absorption spectrum of P3BT solution in ODCB along with the absorption spectrum of P3BT-nw suspension. In addition to the absorption maximum (λₘₐₓ) of the nanowire suspension (λₘₐₓ=502 nm), which is red-shifted from the solution (λₘₐₓ=463 nm), two additional lower-energy shoulder peaks appear at 565 and 615 nm and are characteristic of the crystalline P3BT. The optical absorption spectra of spin coated thin films of P3BT-nw/C₆₁-PCBM (1/1 wt. ratio) nanocomposite (70 nm) and P3BT:C₆₁-PCBM (1:1 wt. ratio) blend (80 nm) on ITO/PEDOT substrates are also shown in FIG. 1D. The absorption features, λₘₐₓ and shoulder peaks, are identical in the P3BT-nw/PCBM nanocomposite and P3BT:PCBM blend films as well as similar to the P3BT-nw suspension. The absolute absorption in the 700-800 nm seen in the thin film spectra (FIG. 1D) is due to the ITO/PEDOT substrate.

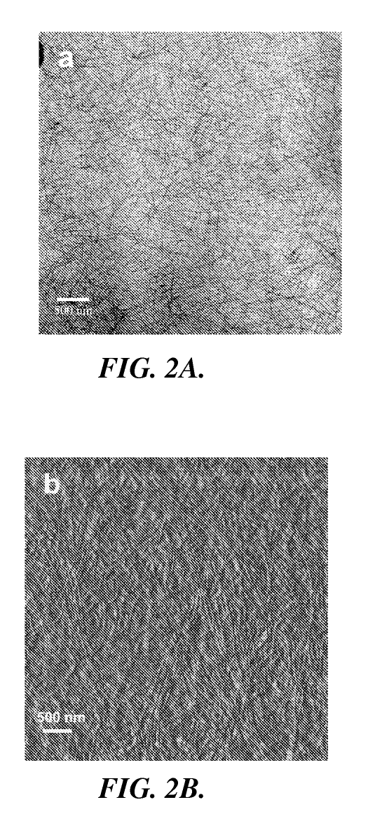

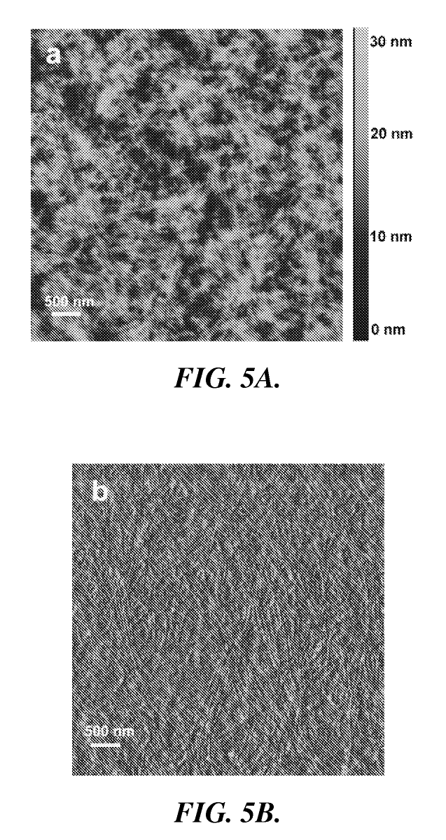

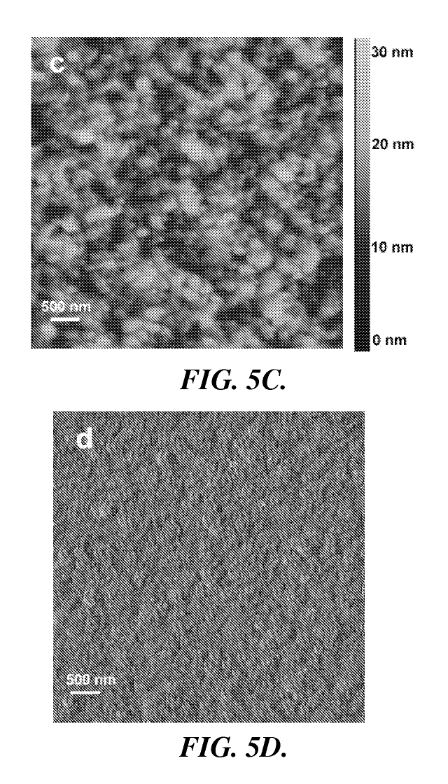

The morphology of P3BT-nw/C₆₁-PCBM nanocomposite films was investigated with transmission electron microscopy (TEM) and atomic force microscopy (AFM). P3BT nanowires with 8-10 nm width and up to 5-10 μm length were observed in the TEM and AFM images (see FIGS. 2A and 2B, respectively). These nanowires form an interconnected network surrounded by a continuous PCBM phase, forming a quasi-bicontinuous nanoscale morphology (illustrated in FIG. 1A). In contrast, more globular domains with no obvious interconnectivity were seen in the AFM image of P3BT:C₆₁-PCBM blend (see FIGS. 5C and 5D).

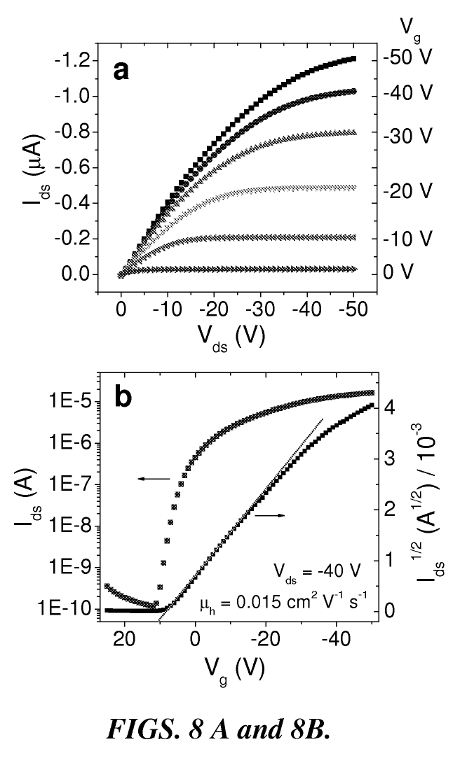

The charge transport properties of the P3BT-nw/fullerene nanocomposites, P3BT:C₆₁-PCBM blends, and P3HT:fullerene blends were investigated by using the field-effect transistor (see Example 1 and FIGS. 8A and 8B). The average field-effect mobility of holes )μₕ) was 8.0×10⁻³ cm² Vs in P3BT-nw/PCBM nanocomposite films but only 3.8×10⁻⁵ cm²/Vs in P3BT:PCBM blend films (Table 1). Clearly, the interpenetrating two-phase morphology enabled by the P3BT nanowires offers far superior hole transport than the phase-separated P3BT blend. A similar comparison of hole mobility among P3BT-nw/C₇₁-PCBM nanocomposite and P3HT:C₇₁-PCBM blend showed that the nanowire was far superior.

TABLE 1
Charge carrier mobility and photovoltaic properties.

| | Thick- | | | | | |
|---|---|---|---|---|---|---|
| | ness | μₕ | V_{oc} | I_{sc} | | PCE |
| Active Layer | [nm] | [cm²/Vs] | [V] | [mA/cm²] | FF | (%) |
| P3BT-nw/C₆₁- | 70 | 8.0 × 10⁻³ | 0.50 | 7.68 | 0.57 | 2.2 |
| PCBM | | | | | | |
| P3BT:C₆₁-PCBM | 80 | 3.8 × 10⁻⁵ | 0.42 | 4.90 | 0.48 | 1.0 |
| P3BT-nw/C₇₁- | 90 | 1.9 × 10⁻³ | 0.60 | 8.43 | 0.59 | 3.0 |
| PCBM | | | | | | |
| P3HT:C₇₁-PCBM | 120 | 5.0 × 10⁻⁴ | 0.61 | 8.67 | 0.57 | 3.0 |

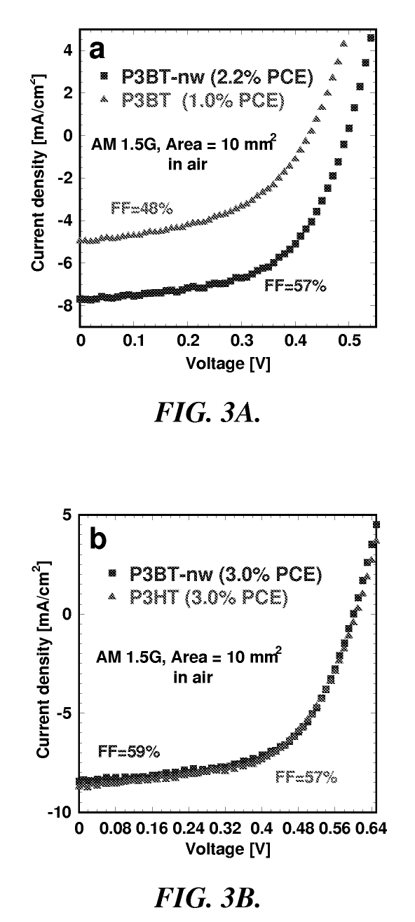

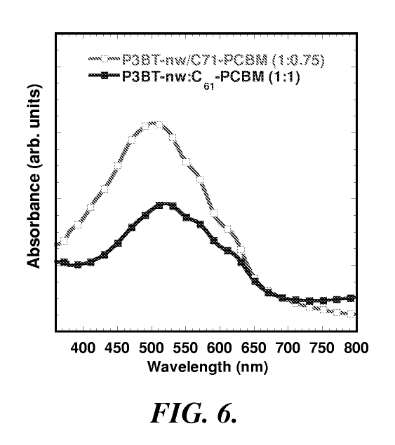

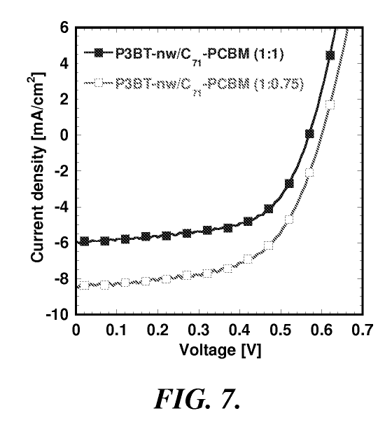

Photovoltaic cells with 10 mm² area were fabricated from P3BT-nw/C₆₁-PCBM (1/1) nanocomposite and P3BT:C₆₁ -PCBM (1:1) blend films and tested in air under 100 mW/cm² AM1.5 illumination (see Example 1 and FIGS. 6 and 7). The current density-voltage characteristics of these two devices are shown in FIG. 3A and the photovoltaic parameters, short-circuit current density (I_{SC}), open circuit voltage (V_{OV}), fill factor (FF), and power conversion efficiency (PCE), are given in Table 1. The photovoltaic cells based on the P3BT nanowires have a 2.2% PCE and indeed are far superior in all performance parameters compared to the conventional P3BT blend cells. The more than two-fold enhancement in efficiency of P3BT nanowire-based solar cells comes from the substantially better charge transport enabled by the nanowire network because both absorbed the same amount of light (FIG. 1D). We also fabricated and tested photovoltaic cells from P3BT-nw/C₇₁-PCBM (1/0.75) nanocomposite and P3HT:C₇₁-PCBM (1:1) blend. The results seen in FIG. 3B and Table 1 show that the power conversion efficiency (3.0%) is identical and the other photovoltaic parameters are comparable for P3BT-nw and P3HT.

As noted above, the present invention provides highly efficient BHJ solar cells using pre-assembled poly(3-butylthiophene) (P3BT) nanowires (NWs) as the donor component along with PC₆₁BM or PC₇₁BM.

In another aspect, the invention provides the use of in-situ self-assembly of polymer semiconductor NWs in blends with PC₆₁BM to create efficient BHJ polymer solar cells. An attractive feature of this approach, illustrated in FIG. 1B, is that it simplifies and collapses the previously separate processes of preparing the polymer semiconductor NWs and the blending with fullerenes into a single process. A power conversion efficiency of 2.52% at the 1:0.5 P3BT:PC₆₁BM ratio was obtained. Details for the preparation and characterization of representative in situ self-assembled polymer semiconductor nanowires in blends with bulk heterojunction acceptor compounds is described in Example 2.

In situ self-assembly of P3BT nanowires. As noted above, in one embodiment, the invention provides a method for preparing P3BT/fullerene (PC₆₁BM or PC₇₁BM) nanocomposite bulk heterojunction solar cells by a process in which the P3BT nanowires (NWs) were self-assembled separately prior to the mixing with the fullerene as illustrated in FIG. 1A. In another embodiment, the invention provides a method for preparing P3BT/fullerene (PC₆₁BM or PC₇₁BM) nanocomposite bulk heterojunction solar cells by a process in which the P3BT nanowires (NWs) were self-assembled in situ, in the presence of the fullerene, as illustrated in FIG. 1B. When a hot (80-90° C.) P3BT:PC₆₁BM blend solution cools to room temperature, and after standing, self-assembly of P3BT NWs occurs in the blend solution over time in very similar ways to the assembly of NWs in a pure P3BT solution.

Evidence of the in-situ self-assembly of P3BT NWs in P3BT:PC₆₁BM blend solutions comes from the solution viscosity, absorption spectroscopy, and the morphology and photovoltaic properties of films prepared from the blend solutions. The P3BT:PC₆₁BM blend solution viscosity was observed to increase substantially with time, reaching a plateau in about 26 h. Transmission electron microscopy (TEM) imaging, absorption spectroscopy, and photovoltaic measurements similarly indicated that the in-situ self-assembly of P3BT NWs.

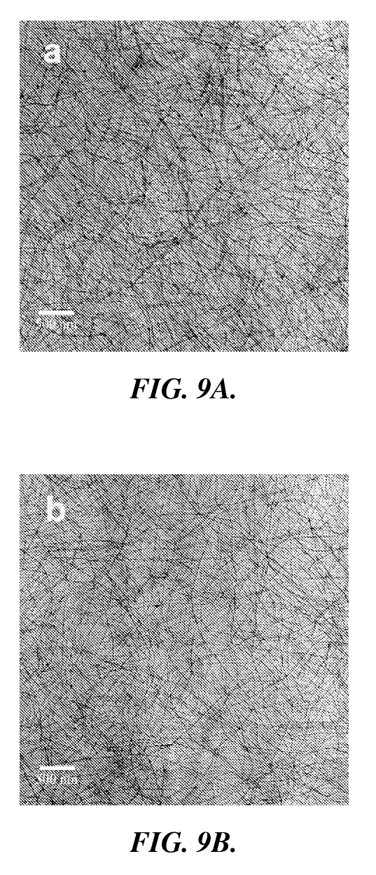

Morphology of P3BT:PCBM Blends. FIGS. 9A and 9B show the bright field TEM images of blend films with P3BT:PC₆₁BM compositions of 1:2 and 1:0.25, respectively. Each film shows a network of P3BT NWs with lengths in the 5-10 microns range. An image analysis based on 200 random measurements of the widths (or diameters) seen in the TEM images of larger magnifications, gave a width range of 11-15 nm; the width of the P3BT NWs observed here is slightly larger than to those formed in ODCB solution without PC₆₁BM. The P3BT NWs have a very high aspect ratio (length/width) of about 500-900.

An interconnected P3BT nanowire network can be clearly seen in both films regardless of the blend composition.

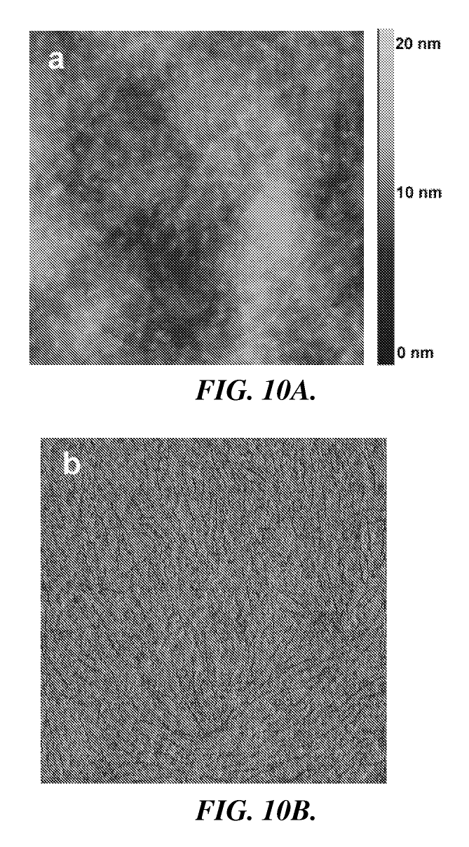

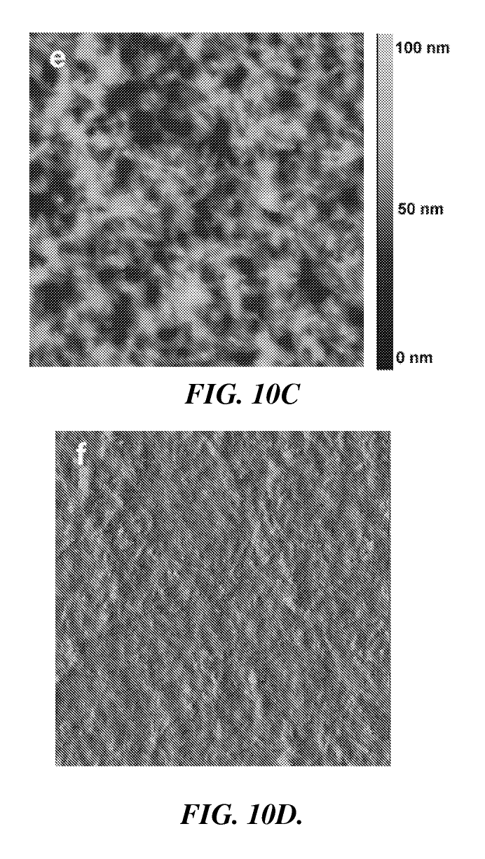

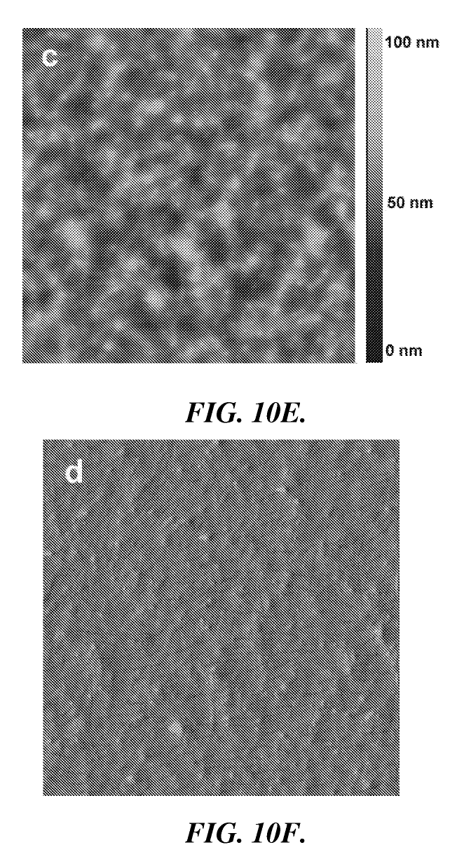

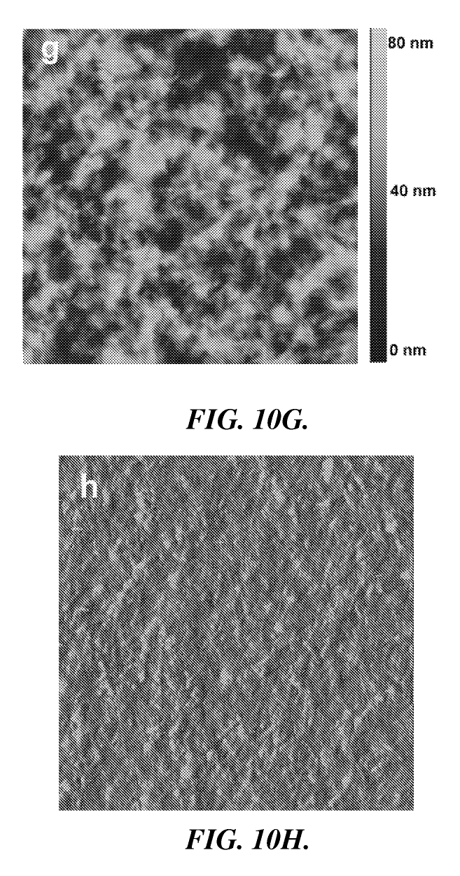

FIGS. 10A-10H show the AFM topography (10A, 10C, 10E, 10G) and phase (10B, 10D, 10F, 10H) images of blend films spin-coated on top of ITO/PEDOT substrates and annealed at 130±10° C. for 10 min. In all the films of different blend compositions, long P3BT nanowires, similar to those seen in the TEM images (FIGS. 9A and 9B) are visible in the phase images. However, the surface morphology seen in the topographic AFM images is quite different as the blend composition changes. In the film which contains the most PC₆₁BM (P3BT:PC₆₁BM =1:2), a continuous PC₆₁BM phase with only a small number of nanowires is seen. The film surface is quite smooth with a root mean-square (rms) roughness of 1.68 nm (FIGS. 10A and 10B). As the PC₆₁BM fraction decreases, such as in films with P3BT: PC₆₁BM ratios of 1:1 and 1:0.5, more and more P3BT nanowires are visible from the surface topography images while PC₆₁BM still forms a continuous phase. The surface roughness in these films is dramatically increased to rms of 7.90 and 13.2 for the 1:1 and 1:0.5 blends, respectively, and many PC₆₁BM crystal domains with tens of nanometer size are also clearly observed (FIGS. 10D and 10F). Further decrease of the PC₆₁BM fraction results in a blend film (P3BT:PC₆₁BM=1:0.25) in which the P3BT nanowires are highly interconnected whereas PC₆₁BM phase exists as isolated domains instead of a continuous phase. The surface roughness of this film has an rms of 11.2 nm.

The morphology of the P3BT:PC₆₁BM blends revealed by TEM and AFM phase images is essentially the same except the increased P3BT NW density in the AFM phase images. However, the different features seen in the AFM topographic images can be accounted for by effects of the annealing. It was confirmed that without annealing the AFM topographic images showed similar interconnected network of P3BT NWs as that seen in the TEM images; in this case, PC₆₁BM was homogeneously dispersed in between the P3BT NWs (not shown) and the overall morphology was similar to that in preformed P3BT NW:PC₆₁BM composite films.

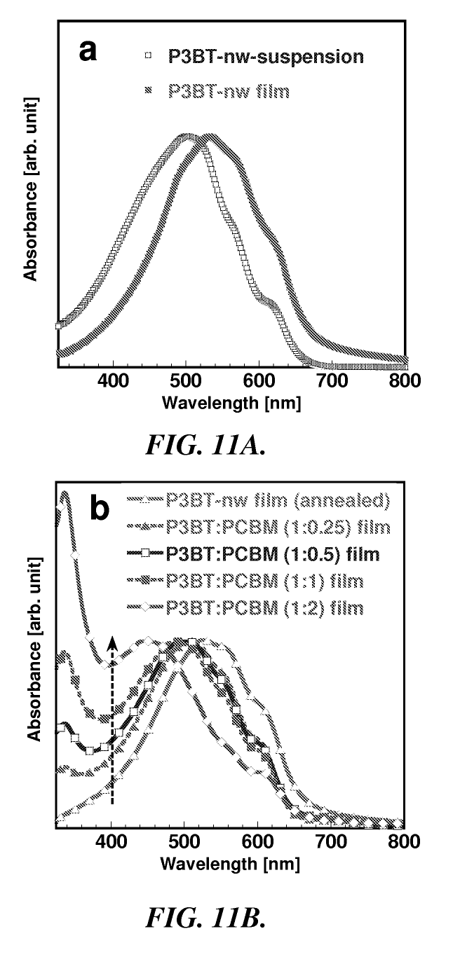

Optical Absorption. The absorption spectra of a suspension of P3BT NWs in ODCB and a spin-coated film of P3BT NWs are shown in FIG. 11A. The P3BT NW suspension shows three absorption peaks at 502, 563, and 616 nm. The later two vibronic peaks are due to the strong π-π stacking within the assembled P3BT NWs. The two vibronic features at 563 and 616 nm in the thin film are at the same wavelengths as in the absorption spectrum of the P3BT NW suspension. The main absorption peak in the film at 532 nm is red-shifted from that observed in the suspension due to the stronger inter-nanowire interaction in the condensed film. The absorption of the P3BT NWs as a thin film is 10 nm red-shifted compared to the reported absorption maximum of solid-state thin film of P3BT in the literature, in which the three peaks were found at 522, 556, and 605 nm, respectively, indicating a more ordered structure in the P3BT nanowires.

FIG. 11B shows the normalized thin film absorption spectra of the P3BT NWs and P3BT:PC₆₁BM blends. The P3BT NW film was spin-coated on a glass slide whereas the blend films were spin-coated on top of ITO/PEDOT substrates. All films were annealed at 130° C. for 10 min. The absorption spectrum of annealed P3BT NW film is identical to the non-annealed one (FIG. 11A). The absorption of P3BT NWs is progressively blue shifted with the loading of PC₆₁BM, the main absorption peak at 532 nm in the pure film is gradually blue-shifted to 450 nm in the 1:2 P3BT:PC₆₁BM film. This blue-shift can be explained by the reduced inter-nanowire interaction disrupted by the presence of PC₆₁BM. However, the characteristic vibronic features at 563 and 616 nm, due to the π-π stacking within the P3BT NWs, show no obvious change even at the highest PC₆₁BM loading (P3BT:PC₆₁BM=1:2). This shows that ordered structure of the P3BT NWs is not disrupted in the blend films.

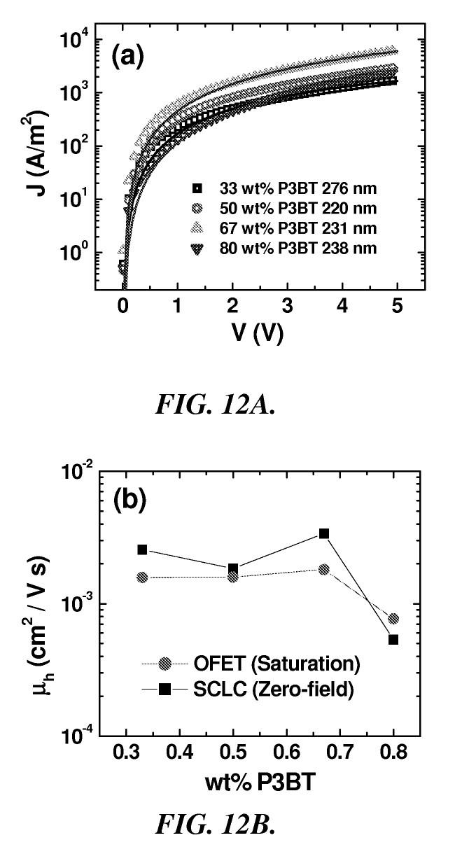

Charge-Transport Properties. Charge-carrier motilities in the P3BT:PC₆₁BM blends were evaluated by both space-charge limited current (SCLC) and organic field-effect transistors (OFETs). FIG. 12A shows the relationship between dark-current density (J) and voltage (V) in the hole-only devices of P3BT:PC₆₁BM blends of different composition. The zero-field mobilities of the P3BT:PC₆₁BM blends were calculated to be 2.56×10⁻³, 1.84×10^{-3, 3.38×10}⁻³ and 5.37×10⁻⁴ cm²/Vs for the 1:2, 1:1, 1:0.5, and 1:0.25 compositions, respectively, and shown in FIG. 12B. These SCLC hole mobilities of the P3BT nanowires in the P3BT/PC₆₁BM blends are one order of magnitude higher than that of P3HT in annealed P3HT/PC₆₁BM (1:1) blends, which is about 2×10⁴ cm²/Vs.

Field-effect mobility was calculated from the standard equation for the saturation region in field-effect transistors. The field-effect hole mobility of P3BT:P₆₁CBM blends ranged from 1.6×10⁻³ cm²/Vs for the 1:2 and 1:1 blends to 7.7×10⁻⁴ cm²/Vs for the 1:0.25 blend (FIG. 12B). The OFET mobility of the in-situ formed P3BT nanowires in the 1:1 P3BT:PC₆₁BM blend is in the same order as the pre-formed P3BT nanowires in nanocomposite with fullerenes. The field-effect electron mobilities of P3BT:PC₆₁BM blends were not observed because our measurements were all done in air.

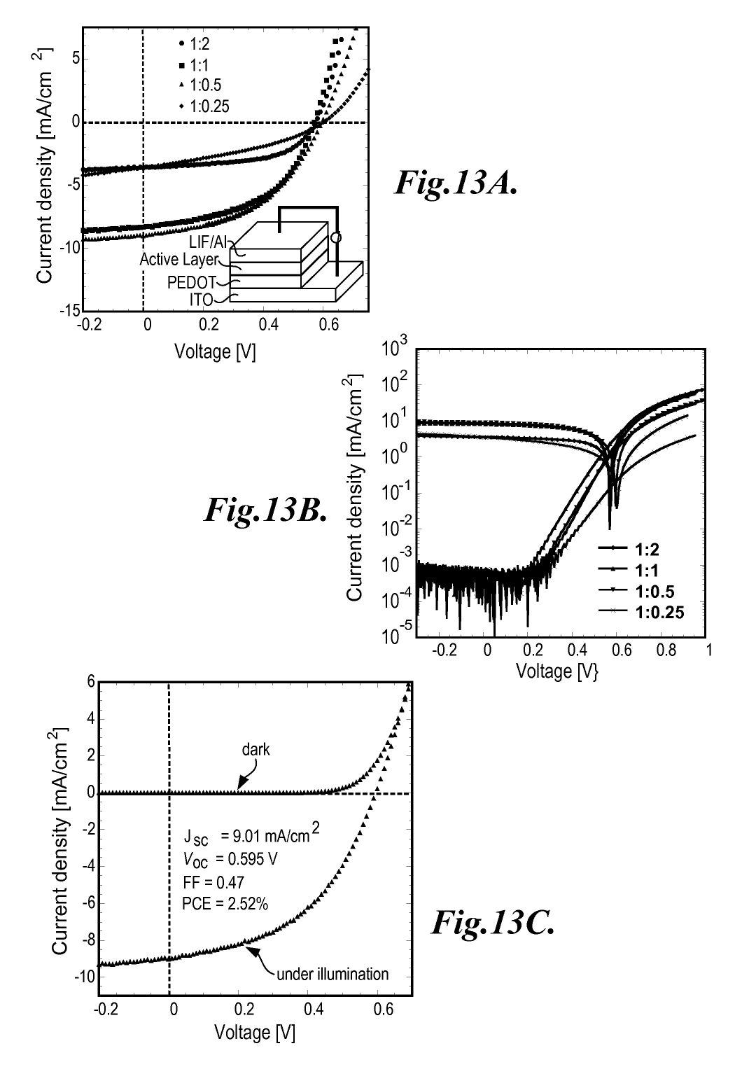

Photovoltaic Properties. Photovoltaic cells incorporating P3BT:PC₆₁BM blends as the active layer were fabricated as 3.57 mm² area and tested under a 100 mW/cm² AM1.5 sunlight illumination in ambient air. The device structure, ITO/PEDOT/P3BT:PC₆₁BM/LiF/Al, is illustrated in the inset of FIG. 13A. The current-voltage curves of the P3BT:PC₆₁BM blend solar cells at different blend compositions are shown in FIGS. 13A-13C. The photovoltaic parameters, the short-circuit current density (J_{SC}), the open circuit voltage (V_{OC}), the fill factor (FF), and the power conversion efficiency (PCE) together with the hole mobilities are summarized in Table 2. The series and parallel (shunt) resistances, respectively, deduced by the inverse gradient of the J-V curves at the open circuit and the short circuit of the J-V curves are also given in Table 2.

TABLE 2
Photovoltaic properties of P3BT:PC₆₁BM blend solar cells.

| P3BT:PC₆₁BM | μ_{h-SCLC} | μ_{h-FET} | rₛ | rₚ | J_{sc} | V_{oc} | | PCE |
|---|---|---|---|---|---|---|---|---|
| (wt:wt) | (cm²/Vs) | (cm²/Vs) | (Ω cm²) | (Ω cm²) | [mA/cm²] | [V] | FF | (%) |
| 1:2 | 2.56 × 10⁻³ | 1.6 × 10⁻³ | 21.1 | 1063 | 3.45 | 0.57 | 0.56 | 1.11 |
| 1:1 | 1.84 × 10⁻³ | 1.6 × 10⁻³ | 13.5 | 467 | 8.29 | 0.57 | 0.51 | 2.39 |
| 1:0.5 | 3.38 × 10⁻³ | 1.8 × 10⁻³ | 18.5 | 413 | 9.01 | 0.60 | 0.47 | 2.52 |
| 1:0.25 | 5.37 × 10⁻⁴ | 7.7 × 10⁻⁴ | 54.5 | 315 | 3.62 | 0.61 | 0.35 | 0.78 |

The performance of the photovoltaic cells greatly depends on the blend composition. At a P3BT:PC₆₁BM blend ratio of 1:2, a power conversion efficiency of 1.11% was observed. When the blend ratio increased to 1:1, the efficiency increased to 2.39%. The best performance was achieved at a P3BT:PC₆₁BM ratio of 1:0.5, in which J_{SC}=9.01 mA/cm², V_{OC}=0.60 V, FF=0.47, and a power conversion efficiency of 2.52% were obtained. Further increase of the relative amount of P3BT NWs to P3BT:PC₆₁BM ratio of 1:0.25, results in a dramatic decrease of the efficiency to 0.78%, although the V_{OC} increased slightly to 0.61V, the highest among the four compositions.

These photovoltaic devices based on P3BT NWs generally had excellent diode characteristics. For example, the 1:0.5 P3BT:PC₆₁BM blend cell, whose current-voltage characteristics are shown in FIG. 13B, showed very high rectification ratios of 2.9×10³ in the dark at +0.60 V and 2.6x10⁴ at +0.85 V. The other blend photovoltaic cells similarly had excellent rectification ratios. The excellent diode characteristics can be understood given the extremely large shunt resistance. From the dark J-V curves in FIG. 13B, the shunt resistances are too large to be calculated. Under illumination, the shunt resistances (rₚ) are dramatically decreased (Table 2).

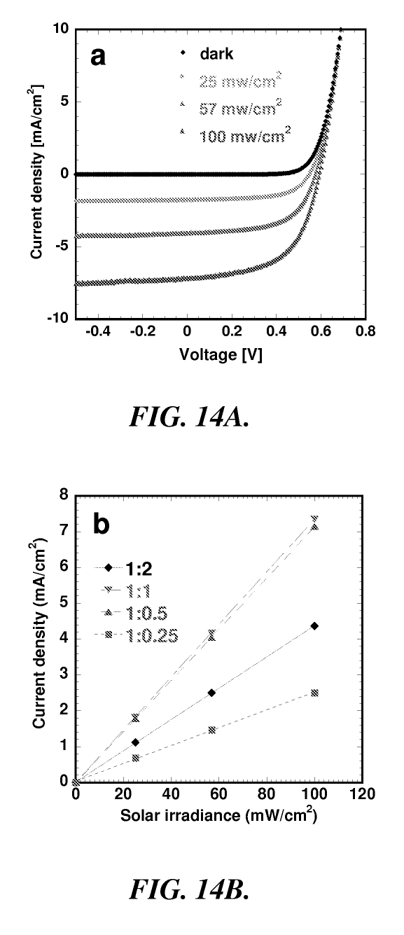

To gain insight into the operation of these P3BT:PC₆₁BM blend solar cells, the light-intensity dependence of the photocurrent was studied. The J-V characteristics of the 1:0.5 P3BT:PC₆₁BM solar cells under illumination of different light intensities are shown in FIG. 14A. The current density as a function of light intensity for the four composition solar cells is shown in FIG. 14B. For all four compositions, J_{SC} shows linear dependence on the light intensity, which indicates no space charge is formed and the short-circuit current density loss is dominated by the monomolecular recombination. The space charge free carrier transport can be understood given the high hole mobilities of the P3BT nanowires within the blends. Such mobilities are comparable to reported electron mobility of PC₆₁BM. However, because the devices were measured in air, the generated charge carriers, especially electron may be trapped by impurities such as oxygen, water, and recombined with opposite charge, leading to low solar cell efficiency. The trapping and monomolecular recombination mechanism is valid if field-effect electron mobility could not be observed in the OFETs.

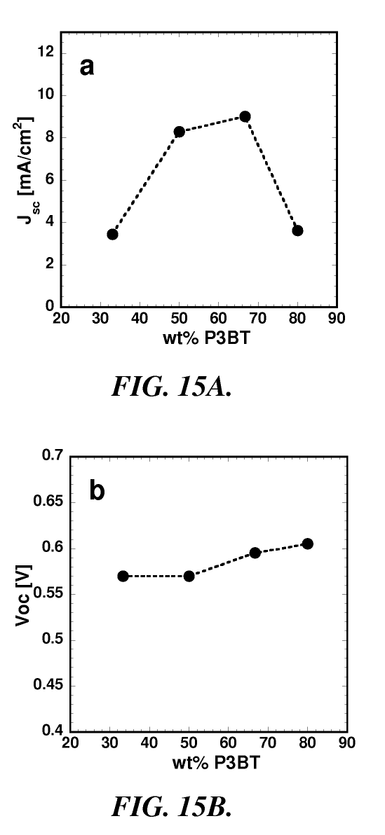

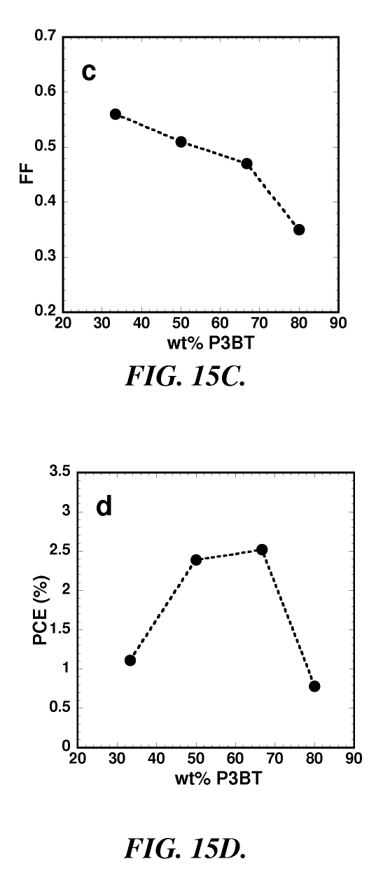

To further understand the relationship between the blend composition and the photovoltaic properties, the dependence of J_{SC}, V_{OC}, FF, and PCE as a function of wt % P3BT was plotted (FIGS. 15A-15D). The P3BT:PC₆₁BM weight ratios of 1:2, 1:1, 1:0.5, and 1:0.25 correspond to 33, 50, 67, and 80 wt% P3BT, respectively. As seen in FIG. 15A, the short-circuit current density as a function of composition (wt % P3BT) has a peak at approximately 66% P3BT and then at high fraction (80%), it dramatically decreased to 3.62 mA/cm². Because the hole mobility and the series resistances are comparable from the 1:2 to the 1:0.5 P3BT:PC₆₁BM blend ratio, the small current density (3.45 mA/cm²) at low P3BT fraction (33%) can be understood as a consequence of poor absorption because P3BT is the main absorber harvesting light in the devices. When the P3BT fraction is 80%, the series resistance dramatically increases to 54.5 Ω cm² from 18.5 Ω cm² in the 1:0.5 P3BT:PC₆₁BM blend and hence the photocurrent in this cell should largely be limited by the high series resistance. The series resistances observed in P3BT:PC₆₁BM solar cells are much higher than those of annealed P3HT:PC₆₁BM blend films, which are less than 8 Ω cm².

The open circuit voltage, V_{OC}, in all the photovoltaic devices is found to be quite stable (FIG. 15D). It increases from 0.57 V at 33% P3BT to 0.61 V at 80% P3BT (FIG. 13B). In contrast, V_{OC} in reported P3HT:PC₆₁BM blend devices was found to be more dependent on the blend composition, increasing by 0.1 V when the PC₆₁BM loading changed from 20% to 80%. The large variation of V_{OC} in P3HT:PC₆₁BM blend devices has been explained in terms of the disruptive role of PC₆₁BM in the intermolecular packing of P3HT, leading to different effective bandgaps of P3HT in the blends. The relatively constant V_{OC} in the present P3BT:PC₆₁BM blend photovoltaic devices is due to the constant optical bandgap of P3BT NWs in the blends. Thus, an important advantage of the P3BT NW approach to the BHJ solar cells is the stability of open circuit voltage.

The fill factor (FF) is another important parameter that affects the solar cell efficiency. The highest FF (0.56) of these P3BT:PC₆₁BM blend solar cells was achieved at the highest PC₆₁BM concentration of 67 wt % (33% P3BT); FF gradually decreased with the decreasing PC₆₁BM fraction (FIG. 15C) until 33% PC₆₁BM and then dramatically decreased to 0.35 in PC₆₁BM fraction of 20%. The variation in FF value may be explained by the different series and shunt resistances in the films with different compositions. The low P3BT concentration (33%) cell shows a more than doubled shunt resistance than the other cells, which compensates the reduction in FF due to a little higher series resistance, leading to the highest FF observed. From a concentration of 50% to 67%, the increase of the series resistance and the decrease of the shunt resistance result in the lowered FF. For the highest P3BT fraction (80%), the dramatically increased series resistance and the much lower shunt resistance account for the lowest FF among all the cells.

The power conversion efficiency (PCE) dependence on blend composition (FIG. 15D) mirrors the short-circuit current density dependence on blend composition (FIG. 15A), indicating that the PCE of the P3BT:PC₆₁BM blend solar cells is dominated by the same factors as for J_{SC}. This can be understood by the relative stable V_{OC} in these P3BT:PC₆₁BM blend solar cells. As is well known, J_{SC} is the result of light absorption, exciton dissociation, and charge transport, which are also critical to the overall PCE. Unlike P3HT:PC₆₁BM solar cells, in which the highest PCE was generally observed in the 1:1 blend composition, the best performance among the present PC₆₁BM:P3BT NW solar cells was obtained from the 1:0.5 composition. It is advantageous to minimize the fullerene component because the fullerene contributes little to the light absorption.

Thus, in another aspect, the invention provides bulk heterojunction P3BT:PC₆₁BM photovoltaic cells created by an in-situ self-assembly of P3BT nanowires as the donor component. The P3BT NWs, self-assembled in the presence of the fullerene acceptor, formed an interconnected network in the blend films. TEM and AFM imaging revealed P3BT NWs with 11-15 nm width and several microns length. High hole mobilities on the order of 10⁻³ cm²/Vs were observed in the P3BT nanowires/PC₆₁BM nanocomposites by both SCLC and field-effect transistors. The photovoltaic properties, especially the short-circuit current density, fill factor, and power conversion efficiency were found to depend strongly on blend composition. A power conversion efficiency of 2.52% was achieved from the 1:0.5 P3BT:PC₆₁BM blend in ambient air. The in-situ self-assembly method provides a means for the rational control of the film morphology in bulk heterojunction polymer solar cells. The performance of the P3BT nanowire/PC₆₁BM solar cells is mainly limited by the monomolecular recombination and the high series resistance.

Film morphology is a factor affecting the nanowire solar cell performance. Annealing at different drying levels resulted in varied morphology because the solid state nanowires restricted the diffusion of the fullerene. Annealing dry film only caused diffusion and aggregation of the fullerene while with nanowire structure not changed, resulting in efficient exciton generation, dissociation, and charge transport, and thus high current density. When wet films were annealed, vertical phase separation was achieved with more fullerene moving to the surface as well as partially dissolving and reorganization of the nanowire, leading to increased open circuit voltage but low current density. A power conversion efficiency of 3.5% was achieved from 1:0.5 P3BT-nw:PC₇₁BM device annealed at wet with J_{SC}=9.2 mA/cm², V_{OC}=0.60, and FF=0.61.

Morphology, charge transport, and photovoltaic performance of P3BT-nw/fullerene blend films was evaluated when annealed at wet, partially dry, and completely dry, as well as without any annealing. The photovoltaic performance, especially the current density and open circuit voltage, was found to be related to the film morphology. Homogenous dispersion of the fullerene in the P3BT-nw matrix in non-annealed device showed relatively poor photovoltaic performance due to low exciton dissociation efficiency and current loss at electrode although highest hole mobility was measured in this film. Thermal annealing resulted in vertical segregation of fullerene and improved exciton dissociation and charge transport efficiency. A current density as high as 10.6 mA/cm² was achieved in film annealed after dry, benefited from high absorption intensity and hole mobility of the nanowires. When film was annealed at wet, P3BT nanowires was partially dissolved which resulted in reduced absorption intensity and thus low current density. However, the highest open circuit voltage in this device compensates the low current density, resulted in better overall power conversion efficiency.

The effects of annealing on the characteristics of poly(3-butylthiophene) (P3BT) nanowires and composites, photovoltaic cells, and field effect transistors that include the nanowires are described in Example 3.

Film drying time and annealing effect on the morphology of pure P3BT nanowires was determined. Four samples were prepared by spin-coating 8 mg/ml P3BT-nw suspension on top of ITO/PEDOT substrates at 1000 rpm for 30 s. The sample was moved to a covered Petri dish for aging after spin-coating. The color of the as prepared wet film was orange and it gradually changed to deep purple from the edge to the center. After about 50 min, there was no more obvious color change from the human eye although there might be some residue solvents in the film. The color change indicates the interaction between the nanowires revealed by the enhanced absorption. Three of films were annealed after 3 min, 50 min, and 100 min aging, respectively. The annealing temperature and duration were 175° C. and 10 min. The other film was put in a 50° C. vacuum oven after 100 min aging for further removing of the residue solvent. The four film treatment conditions: 3 min aging and annealing (condition A); aging time at which film color changed from orange to purple and annealing (condition B); 100 min aging and annealing; 100 min aging and non-annealing (either dried in a 50° C. vacuum oven or in a high vacuum chamber, condition D), were used for testing the morphology and photovoltaic performance change as a function of the film annealing condition. Drying time (color change) of the nanowire films is longer than that prepared from solution, which is about 5-8 min. This is because in solution the polymer exists as free molecular and can move and reorganize quickly whereas in the nanowire suspension, the polymer is already in solid state and hard to move and interact with other nanowires.

The optical absorption spectra of the four nanowire films treated under the four conditions were measured. Compared to the nanowire suspension, the absorption of the thin films all red-shifted with the intensity greatly enhanced due to more condensed interaction between the polymers. For films with aging time longer than 50 min, their absorption spectra are almost identical to each other. The main absorption peak of these films appears at 513 nm, red-shifts about 40 nm, and the two characteristic peaks of the nanowires locate at 565 and 615 nm, identical to that of the nanowire suspension. For film annealed after 3 min, however, the main absorption peak appear at 505 nm with the two feature shoulder at 548 and 600 nm, all blue-shifted compared to the other films. The blue-shift of the absorption reveals the reduced interaction between the polymers. As mentioned above, at aging time of 3 min, the film was still wet, so the large amount of solvent may dissolve some of the nanowires resulting in reorganization of the polymer.

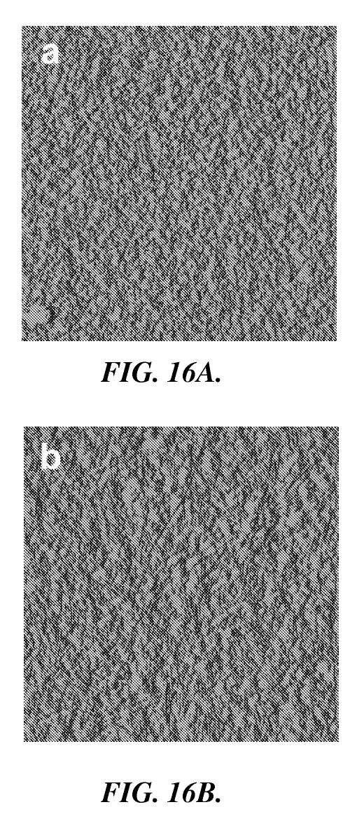

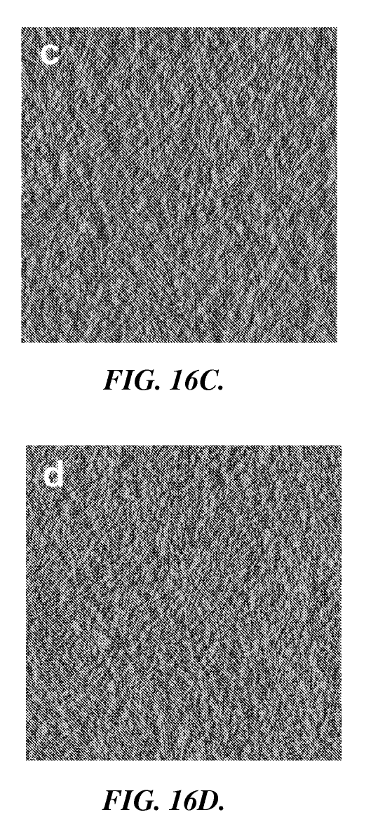

To investigate the morphology change, AFM images were performed on the four films and the results are shown in FIGS. 16A-16D. For films after 100 min aging, whether annealed or not, the long and interconnected nanowires can be seen (FIGS. 16C and 16D). These nanowires are basically the same as that of the TEM image except for higher density due to much thicker film. The difference between the two images is that the nanowires in the annealed film are much clearer (straighter) and well aligned than that in the vacuum dried film, indicating more ordered structure after annealing. For 50 min aging and annealed film (FIG. 16B), the nanowires can be seen, but at some area the nanowires appear bunched together and formed some small domains. For film undergoing the shortest aging time (3 min), polymer domains become dominate although the nanowires are still detectable.

To further understand the crystalline of the P3BT nanowires and the structure change upon annealing, X-ray diffractions (XRD) were measured directly on the films. The sharp peaks at 2-theta 20.1 and 30.1 degree come from the ITO substrate. All films show a clear peak at around 6.8 degree, corresponding to (100) diffraction of the interlayer interaction. The broad peaks at about 25 degree can be assigned to the (010) diffraction, which corresponds to the π-π stacking of the polymer backbone. Among the four films investigated, the (100) diffraction in the 100 min aging and vacuum dried film is broad with the intensity much lower than the others. The d-spacing of (100) diffraction is 1.26 nm in this film. After annealing, the (100) peak becomes very sharp due to the enhanced side chain interaction with the d-spacing increased to 1.28 nm. This is consistent with the better aligned nanowires in this film as observed from the AFM image (FIG. 16B). The 50 min aging and annealed film shows very similar XRD pattern to the 100 aging and annealed film, the small crystalline domains observed in the AFM image do not change the bulk structure of the nanowires. For 3 min aging and annealed film, on contrast, the d-spacing of (100) diffraction increases to 1.31 nm indicating reduced interchain interaction due to partially dissolving of the nanowires, in consistent with the blue-shift and decreased intensity in the absorption. However, the (100) diffraction intensity in this film is the strongest among the four films. The increased crystalline domain size can be attributed to the aggregation of the polymer.

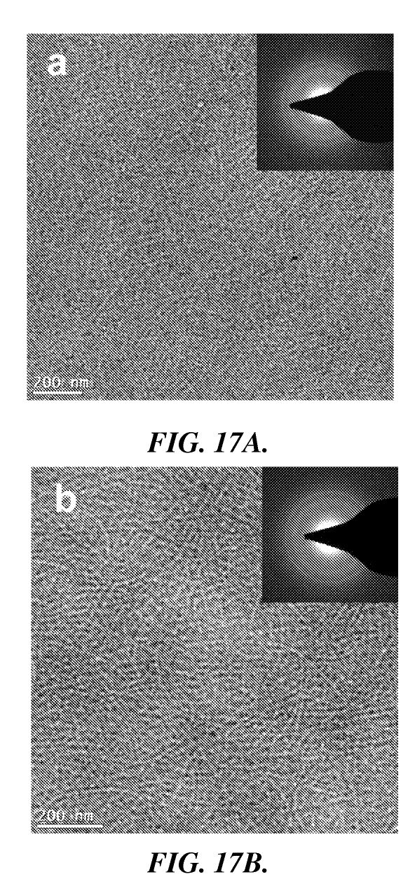

To understand the bulk morphology change of the P3BT nanowires upon annealing, bright-field TEM images and their electron diffractions were acquired in film under condition A and condition D (FIGS. 17A and 17B). The films for this measurement were peeled from the ITO substrates by water floating. For the 100 min aging and vacuum dried film, the long crosslinked nanowires were seen indicating the same nanowire structure. The three strong electron diffraction rings at q of 0.8, 0.16, and 2.6 nm⁻¹ correspond to the (100), (200), and (010) diffraction, respectively. For the 3 min aging and annealed film, as expected, many black spots at sizes of tens of nanometers are seen together with the nanowires cross the whole film, in consistent with that observed in AFM image. The high intensity of the electron diffraction in the non-annealed film reveals more ordered structure of nanowires.

To investigate the charge transport property of the nanowires, hole mobilities of P3BT-nw films were evaluated by both organic field-effect transistors (OFETs) and space-charge limited current (SCLC). Field-effect mobility was calculated from the standard equation for the saturation region in field-effect transistors. The OFET mobilities of the P3BT-nw films treated under conditions A, B, C, and D are 3.53×10⁻³, 4.92×10⁻³, 5.03×10⁻³, and 4.68×10⁻³ cm²/Vs, respectively.

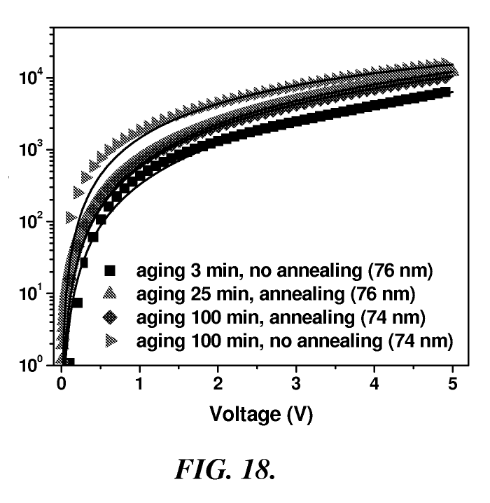

FIG. 18 shows the relationship between dark-current density (J) and voltage (V) in the hole-only devices of P3BT-nw films under four different aging and annealing conditions. The solid lines in FIG. 18A represent the fitting curves. The zero-field mobilities of the P3BT-nw films treated under condition A to D were calculated to be 1.31×10⁻⁴, 1.25×10⁻⁴, 7.47×10⁻⁵ and 3.66×10⁻⁵ cm²/Vs, respectively.

The morphology and charge transport change of the P3BT nanowires in the blends with fullerene were investigated to understand the nanowire bulk heterojunction solar cell performance. P3BT-nw/PC₇₁BM blend films for this purpose were prepared under similar conditions as that of the pure P3BT-nw films. Film drying time, the color change from orange to deep purple, was found to depend on the blend composition: the more density of nanowires, the longer the drying time. For pure P3BT-nw film, as mentioned above, the drying time was about 50 min, for 1:0.5 and the 1:1 P3BT-nw: PC₇₁BM blend, the drying time was about 45 and 35 min, respectively.

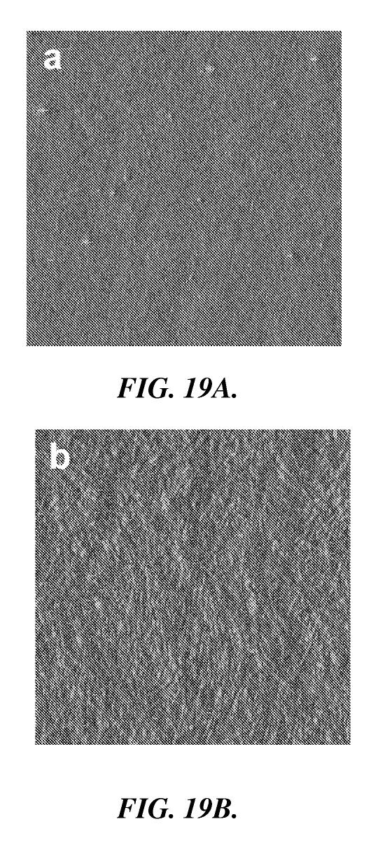

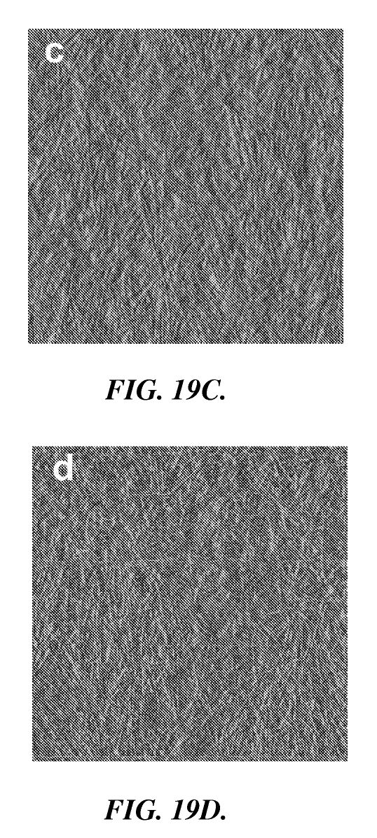

FIGS. 19A-19D shows the phase AFM images of P3BT-nw: PC₇₁BM (1:1 wt %) blend films prepared under the four conditions.

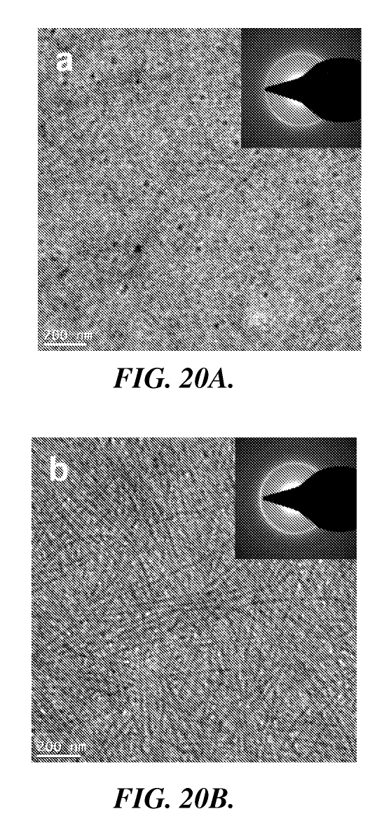

Bright-field TEM images and the electron diffraction of the blend films were acquired to understand and compare the bulk morphology of the blend with the pure nanowire film (FIGS. 20A and 20B). For 100 min aging and vacuum dried blend, the interconnected P3BT nanowire network can be clearly seen from image, similar to the corresponding pure nanowire film (FIG. 17B). For 3 min aging and annealed film, the nanowires are not clear as that of 100 min aging film, but they are still detectable.

The absorption spectra of the blend films (four different processing conditions with the P3BT-nw: PC₇₁BM composition of 1:0.5 and 1:1) are similar to that of the pure P3BT-nw films. For films with the aging time longer than their color change (condition C to D), the absorption characteristics are identical to each other with the characteristic peaks same to that of the nanowire suspension, indicating the survival of the nanowires. For 3 min aging and annealed film, similar to that of the pure nanowire film, both main peak and feature absorption shoulders are blue-shifted, indicating similar structure change. The difference between the blend and pure polymer nanowire films is that the main absorption peak of the blend films show smaller red-shift (about 25 nm) to that of the pure nanowire film because the reduced intra-nanowire interaction due to the addition of the fullerene. The difference in the absorption intensity between condition A and condition D is more distinct in the 1:1 film than the 1:0.5 film due to reduced nanowire content.

XRD patterns of the blend films with the P3BT-nw: PC₇₁BM composition of 1:0.5 and 1:1 were obtained and were similar to that of the pure P3BT-nw films processed under similar conditions, further confirming the same structure change in corresponding films.

OFET devices of P3BT-nw: PC₇₁BM (1:1) blend films were fabricated and tested under the same conditions as that of pure nanowire films. The OFET mobilities were calculated to be 1.89×10⁻³, 5.13×10⁻³, 4.35×10⁻³, and 7.55×10⁻³ cm² Vs, respectively, for condition A, B, C, and D, respectively. The mobility of the blend films follows the same trend as that of the pure nanowire films with the lowest value observed in condition A and the others comparable to each other. The SCLC hole mobility of P3BT-nw: PC₇₁BM blend films with different compositions were also measured. The zero-field mobilities of the 1:0.5 P3BT-nw: PC₇₁BM blend were calculated to be 1.31×10⁻⁴, 1.25×10⁻⁴, 7.47×10⁻⁴, and 3.66×10⁻⁴ cm²/Vs, respectively, for film treatment conditions from A to D. The corresponding values for the 1:1 P3BT-nw: PC₇₁BM blend are 4.43×10⁻⁵, 8.20×10⁻⁵, 9.62×10⁻⁵ cm²/Vs, and 3.65×10⁻⁴ cm²/Vs, respectively.

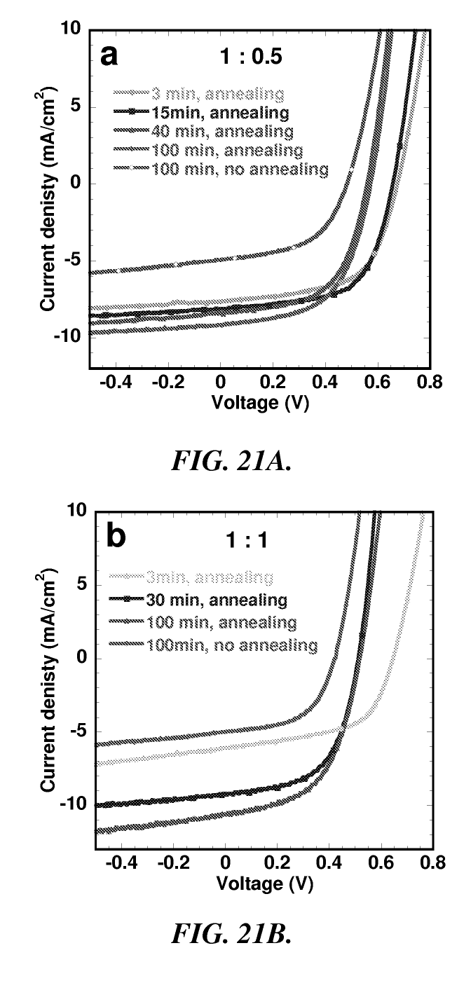

Photovoltaic cells with a structure of ITO/PEDOT/P3BT-nw: PC₇₁BM/LiF/Al were fabricated as 3.57 mm² area and tested under a 100 mW/cm² AM1.5 sunlight illumination in ambient air. The current-voltage curves of the P3BT-nw: PC₇₁BM blend solar cells at compositions of 1:0.5 and 1:1 are shown in FIGS. 21A and 21B. The photovoltaic parameters, the short-circuit current density (J_{SC}), the open circuit voltage (V_{OC}), the fill factor (FF), and the power conversion efficiency (PCE) together with the series and parallel resistance deduced by the inverse gradient of the J-V curves are summarized in Table 3.

TABLE 3
Summary of the photovoltaic properties of P3BT-nw/PC₇₁BM solar cells.

| P3BT- | Film processing | SCLC-hole | Rₛ | Rₚ | I_{sc} | V_{oc} | | PCE |
|---|---|---|---|---|---|---|---|---|
| nw:PC₇1BM | conditions | (cm²/V s) | (Ω cm²) | (Ω cm²) | (mA/cm²) | (V) | FF | (%) |
| 1:0.5 | 3 min aging, | 1.31 × 10⁻⁴ | 14.3 | 652 | 7.63 | 0.67 | 0.61 | 3.10% |
| | annealing | | | | | | | |
| | 15 min aging, | 1.42 × 10⁻⁴ | 11.2 | | 8.12 | 0.66 | 0.63 | 3.35% |
| | annealing | | | | | | | |
| | 45 min aging, | 1.25 × 10⁻⁴ | 10.7 | 560 | 8.25 | 0.56 | 0.58 | 2.69% |
| | annealing | | | | | | | |
| | 100 min aging, | 7.47 × 10⁻⁵ | 11.1 | 372 | 9.16 | 0.57 | 0.57 | 3.00% |
| | annealing | | | | | | | |
| | 100 min aging, | 3.66 × 10⁻⁴ | 20.2 | 510 | 4.07 | 0.46 | 0.51 | 0.96% |
| | no annealing | | | | | | | |
| 1:1 | 3 min aging, | 4.43 × 10⁻⁵ | 13.4 | 740 | 6.02 | 0.65 | 0.58 | 2.27% |
| | annealing | | | | | | | |
| | 35 min aging, | 8.20 × 10⁻⁵ | 11.1 | 556 | 9.16 | 0.51 | 0.56 | 2.63% |
| | annealing | | | | | | | |
| | 100 min aging, | 9.62 × 10⁻⁵ | 11.2 | 367 | 10.58 | 0.52 | 0.54 | 2.93% |
| | annealing | | | | | | | |
| | 100 min aging, | 3.65 × 10⁻⁴ | 34.87 | 505 | 5.27 | 0.42 | 0.58 | 1.18% |
| | no annealing | | | | | | | |

For 1:0.5 P3BT-nw:PC₇₁BM composition, the best performance was achieved in 3 min aging and annealed device (condition A) with an average PCE of 3.10% while for 1:1 composition, the highest PCE was obtained in 100 min aging and annealed device (condition C) with the PCE of 2.93%. Under the four film processing conditions investigated in this study, the changing of the photovoltaic parameters such as the J_{SC}, the V_{OC}, and the FF follow the same trend in both compositions. Under condition A, devices have the highest open circuit voltage but the lowest current density. The J_{SC} and V_{OC} are 7.63 mA/cm², 0.67 V and 6.02 mA/cm², 0.65 V, respectively, for 1:0.5 and 1:1 P3BT-nw:PC₇₁BM compositions. Under condition B, the J_{SC} for the 1:0.5 and 1:1 devices increased to 8.25 and 9.16 mA/cm² with the V_{OC} decreased to 0.56 and 0.51 V, respectively. As the film aging time increased to 100 min, under condition C, the J_{SC} further increased to 9.16 and 10.58 mA/cm² with the V_{OC} values of 0.57 and 0.51 V, respectively, for the 1:0.5 and 1:1 compositions. For 100 min aging and annealing free devices, both current density and open circuit voltage are dramatically deceased to 4.07 mA/cm² and 0.46 V, and 5.27 mA/cm² and 0.42 V, respectively, for 1:0.5 and 1:1 devices. In both compositions, the highest FF was achieved in condition A and gradually decreased as the film drying time increased.

The following examples are provided for the purpose of illustrating, not limiting the invention.

### EXAMPLES

### Example 1

### The Preparation and Characterization of Representative Nanowires, Composites, and Related Structures

In this example, the preparation and characterization of representative (P3BT) nanowires and composites, photovoltaic cells, and field-effect transistors that include the nanowires are described.

Materials. Poly(3-butylthiophene) (P3BT; 97% head-to-tail regioregularity) was purchased from Aldrich. Poly(3-hexylthiophene) (P3HT; 98.5% head-to-tail regioregularity; M_{W}: 30,000-80,000), [6,6]-phenyl-C₆₁ butyric acid methyl ester (C₆₁-PCBM, >99.5%), and [6,6]-phenyl-C₇₁ butyric acid methyl ester (C₇₁-PCBM, >99.0%) were obtained from American Dye Source Inc. All the chemicals were used as received. Poly(3,4-ethylenedioxythiophene):poly(styrene sulfonate) (PEDOT) (Baytron P VP AI 4083) was bought from H. C. Stark (Newton, Mass.) and diluted by adding deionized water (3 PEDOT: 1 water) and passed through a 0.45 μm filter before spin-coating.

P3BT Nanowire Preparation. 5 mL nitrogen-degassed 1,2-dichlorobenzene (ODCB) solvent was added to a 10 ml bottle containing 30 mg P3BT sample; the suspension (6 mg/mL) was stirred for 24 h at 90-100° C. until P3BT was completely dissolved. The hot solution was filtered through a 0.45 μm filter and the filtrate was put in a dark environment for 72 h to allow P3BT molecules to self-assemble. The original orange brown color of the solution changed to dark violet after the P3BT nanowires (P3BT-nw) were formed as a dispersion. The P3BT nanowire suspension was found to be quite stable. The nanowires did not dissolve in ODCB by dilution and did not precipitate in over one month of standing. However, the nanowires re-dissolved upon heating (90-100° C.).

Preparation of P3BT-nw/Fullerene Nanocomposites and P3BT: Fullerene Blends. Fullerene solutions (60 mg/mL) were made by dissolving fullerene (either C₆₁-PCBM or C₇₁-PCBM) in ODCB at 40° C. under stirring and then passing through a 0.2 μm filter. The P3BT-nw/C₆₁-PCBM (1/1 wt. ratio) and P3BT-nw/C₇₁-PCBM (1/0.75 wt. ratio) nanocomposites were prepared by mixing 1 mL P3BT-nw suspension with 0.1 mL C₆₁-PCBM and 0.075 mL C₇₁-PCBM solutions, respectively. The concentration of these two nanocomposites was 10.9 and 9.8 mg/mL, respectively. P3HT:C₇₁-PCBM (1:1) blend was prepared from 30 mg/mL P3HT solution and 60 mg/mL C₇₁-PCBM solution. P3BT:C₆₁-PCBM (1:1 wt. ratio) blend was made by mixing 0.5 mL of a just-filtered P3BT solution (12 mg/mL) with 0.1 mL C₆₁-PCBM solution and kept warm before spin coating of thin films. The total concentration of P3BT:C₆₁-PCBM (1:1) blend was 20 mg/mL. At a spin-coating speed of 1000 rpm, the film thickness cast from 10.9 mg/mL P3BT-nw/C₆₁-PCBM nanocomposite was 70 nm due to the high viscosity of the P3BT nanowire suspension, while the same concentration P3BT:C₆₁-PCBM (1:1) blend only makes 30-40 nm thin films. 20 mg/mL P3BT:C₆₁-PCBM blend was used to make thin films with a 80 nm thickness, which is comparable to that of 10.9 mg/mL P3BT-nw/C₆₁-PCBM nanocomposite.

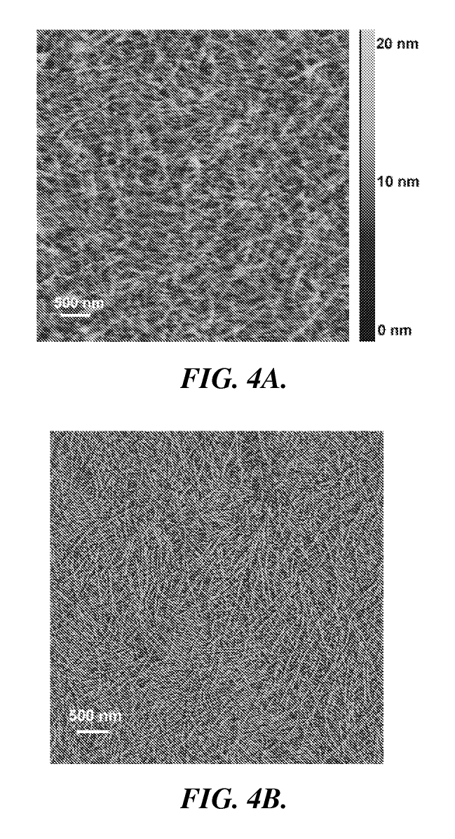

AFM Imaging. The films for atomic force microscopy (AFM) imaging of surface morphology were spin-coated on a silicon wafer substrate for P3BT nanowires and on ITO/PEDOT substrates for P3BT/fullerene nanocomposite and P3BT: fullerene blend. The AFM images were acquired by using a Dimension 3100 Scanning Probe Microscope (Veeco Instruments Inc., Woodbury, N.Y.) in standard tapping mode. The AFM images of P3BT nanowires are shown in FIG. 4A, from which the nanowire structure can been clearly seen. Similar nanowires surrounded by a continuous PCBM phase are observed in P3BT-nw/C₆₁-PCBM (1/1) nanocomposite film as shown in FIGS. 5A and 5B, whereas only globular domains appear in P3BT:C₆₁-PCBM blend (1:1) blend film (FIGS. 5C and 5D).

Fabrication and Testing of Photovoltaic Cells. ITO-coated glass substrates (10±2 Ω/□, Delta Technologies, Stillwater, Minn.) were cleaned sequentially in ultrasonic bathes of acetone, deionized water and isopropanol and dried at 60° C. in a vacuum overnight. The substrates were spin-coated with 40 nm poly(3,4-ethylenedioxythiophene): poly(styrene sulfonate) (PEDOT) buffer layer and dried at 150° C. for 10 min under vacuum. The active layers were spin-coated on the top of PEDOT from P3BT-nw/fullerene nanocomposites or P3BT: fullerene blends at a speed of 1000 rpm for 30s. Films of P3BT-nw/C₆₁-PCBM (1/1) nanocomposite and P3BT:C₆₁-PCBM (1:1) blend were spin-coated in air and dried in a vacuum oven at 60° C. overnight. Films of P3BT-nw/C₇₁-PCBM composites (1:1 and 1:0.75) and P3HT:C₇₁-PCBM (1:1) blend were spin-coated and annealed at 110° C. for 5 min in a glove box. Film thickness was measured by Alpha-Step 500 profilometer (KLA-Tencor, San Jose, Calif.). Although the same spin-coating speed was used for all the active layers, due to the different spin-coaters, the film thickness was different from similar concentration nanocomposites. The thickness of P3BT-nw/C₆₁-PCBM (1:1) film was about 70 nm while films of P3BT-nw/C₇₁-PCBM (1:1) and P3BT-nw/C₇₁-PCBM (1:0.75) was around 90 nm. The cathode of 1.0 nm LiF and 80 nm aluminum layers were sequentially deposited through a shadow mask on the top of the active layers under a vacuum lower than 10-6 Torr. Each substrate contains 9 solar cells with the active area of 10 mm². A conductive wire was connected on the top of each pixel by conductive epoxy and heated at 50° C. for 20 min for the epoxy to dry before measurement of photovoltaic properties. Current-voltage characteristics were measured by using a HP4155A semiconductor parameter analyzer (Yokogawa Hewlett-Packard, Tokyo) under a 100 mW/cm² 1.5 AM sunlight illumination from a filtered Xe lamp. All the characterization steps were carried out under ambient laboratory air.

UV-Vis absorption spectra of P3BT-nw/P P3BT-nw/C₇₁-PCBM (1:0.75) and P3BT-nw/C₆₁-PCBM (1:1) are shown in FIG. 6. The P3BT-nw/C₇₁-PCBM (1:0.75) shows higher absorbance due to its higher thickness.

Current-voltage curves of P3BT-nw/C₇₁-PCBM with a ratio of 1:1 and 1:0.75 are given in FIG. 7. The short-circuit current density (I_{SC}), open circuit voltage (V_{OC}), fill factor (FF), and power conversion efficiency (PCE) obtained from solar cell with 1:1 composition are 5.94, 0.57, 0.60, and 2.0%, respectively. For 1:0.75 composition, these data are 8.43, 0.59, 0.60, and 3.0%, respectively. Because both solar cell devices were prepared under the same condition and they have similar film thickness, the different photovoltaic properties come from the different ratio between the P3BT nanowire donor and fullerene acceptor. This is different from that of P3HT heterojunction solar cells, in which the best donor acceptor ratio is about 1:1.

Field-Effect Transistor Fabrication and Characterization. Field-effect transistors were fabricated on heavily-doped silicon substrates with thermally grown silicon dioxide gate insulator (100 nm). Interdigitated source and drain electrodes with Ti/Au were patterned on top of the substrates by photolithography to make bottom-contact/bottom-gate devices with channel width of 3300 μm and length of 100 μm. Substrates were cleaned by ultrasonication with acetone and isopropyl alcohol, and purged with argon. Self-assembled monolayer of octyltriethoxysilane was formed on top of silicon dioxide surface by immersing substrates in toluene solution (1 mM), and followed by placing on hot plate at 120° C. for 20 min. Each of the solution used for solar cell fabrication was diluted using ODCB, and deposited on the substrates by spin-coating (2000-3000 rpm). Devices were dried in the vacuum at room temperature overnight. The film thickness measured by using a Alpha-Step 500 profilometer was 11-15 nm (±1 nm). Electrical characteristics of the devices were measured on a Keithley 4200 semiconductor characterization system (Keithley Instruments Inc. Cleveland, Ohio). All the measurements were done under dark condition in air. Output and transfer characteristics of a P3BT-nw/C₆₁-PCBM (1/1) nanocomposite thin-film transistor are shown in FIGS. 8A and 8B, respectively. Field-effect mobility was calculated from the standard equation for saturation region in metal-oxide-semiconductor field-effect transistors: I_{ds}=μ(W/2L)Cᵢ(V_{g}-Vₜ)², where I_{ds} is drain-source current, μ is field-effect mobility, W and L are the channel width and length, Cᵢ is the capacitance per unit area of the gate insulator (Cᵢ=33 nF/cm²), V_{g} is the gate voltage, and Vₜ is the threshold voltage.

### Example 2

### The Preparation and Characterization of Representative In Situ Self-Assembled Nanowires, Composites, and Related Structures

In this example, the preparation and characterization of representative in situ self-assembled (P3BT) nanowires and composites, photovoltaic cells, and field-effect transistors that include the nanowires are described.

Poly(3-butylthiophene) (P3BT, 97% head-to-tail regioregularity) was purchased from Aldrich. The [60] fullerene, [6,6]-phenyl-C₆₁-butyric acid methyl ester (PCBM, >99.5%), was obtained from American Dye Source, Inc. (Quebec, Canada). All the chemicals were used as received without further purification. Poly(3,4-ethylenedioxythiophene):poly(styrene sulfonate) (PEDOT) (Baytron P VP AI 4083) was purchased from H. C. Stark (Newton, Mass.) and diluted with deionized water (PEDOT:H₂O=4:1 v/v) and passed through a 0.45 μm filter before spin-coating.

P3BT and PC₆₁BM solutions were prepared by dissolving them separately in nitrogen-degassed 1,2-dichlorobenzene (ODCB). The P3BT solution (10 mg/mL) was heated at 90-100° C. under stirring for 24 h to obtain a completely dissolved hot solution, which was filtered by using a 0.45 μm filter. PC₆₁BM solutions (60 mg/mL) were stirred at 40° C. overnight and passed through a 0.2 μm filter. The P3BT:PC₆₁BM blends were made by mixing the just-filtered hot P3BT solution with PCBM solution at different ratios. The concentration of P3BT:PC₆₁BM blends with the weight ratio of 1:2, 1:1, 1:0.5, and 1:0.25 correspond to a concentration of 22.5, 17.1, 13.8, and 12.0 mg/mL, respectively. The blend solutions were stored in a glove box for P3BT nanowires to self-assemble before they were used for fabricating solar cells and/or for characterization purposes.

Solar cells were fabricated by first spin-coating a PEDOT buffer layer on top of ITO-coated glass substrates (10 Ω/□, Shanghai B. Tree Tech. Consult Co., Ltd, Shanghai, China) at 1500 rpm for 60 s and dried at 150° C. for 10 min under vacuum. The thickness of PEDOT was around 60 nm. The active blend layer was spin-coated on top of the PEDOT layer from the P3BT:PC₆₁BM blend at a speed of 1000 rpm for 30 s and annealed on a hot plate at 130±10° C. for 10 min in a glove box. This is because of the high viscosity of the blend solutions which contain P3BT nanowires. After cooling down, the substrates were taken out of the glove box and loaded in a thermal evaporator (BOC Edwards, 306) for the deposition of the cathode. The cathode consisting of 1.0 nm LiF and 80 nm aluminum layers was sequentially deposited through a shadow mask on top of the active layers in a vacuum of 8×10⁻⁷ torr. Each substrate contained 5 solar cells with an active area of 3.57 mm². Devices for space-charge limited current (SCLC) measurement were fabricated similar to those of solar cells. The main difference is that in order to facilitate hole-only injection and transport, gold electrode was deposited instead of the lithium fluoride (LiF) and aluminum cathode in the solar cells. Film thickness was measured by Alpha-Step 500 profilometer (KLA-Tencor, San Jose, Calif.).

Current-voltage characteristics of both solar cells and SCLC devices were measured by using a HP4155A semiconductor parameter analyzer (Yokogawa Hewlett-Packard, Tokyo). The light intensity of 1.5 AM sunlight from a filtered Xe lamp was controlled by using a set of neutral density filters. The SCLC characteristics were measured under dark conditions. All the characterization steps were carried out under ambient laboratory air.

Field-effect transistors were fabricated on heavily-doped (n-type) silicon substrates with thermally grown silicon dioxide (300 nm). Doped silicon acted as common gate electrode and silicon dioxide as gate insulator. Source and drain electrodes were patterned on top of the substrates by using photolithography and thermal evaporation of 2 nm thick chromium and 60 nm thick gold. The bottom-contact/bottom-gate devices had channel width of 800 μm and length of 20 μm. Substrates were cleaned by ultrasonication with acetone and isopropyl alcohol, and purged with argon. Octyltriethoxysilane (OTS-8) monolayer was deposited on the substrates in vacuum dessicator at 60° C. for more than 6 hours, and crosslinked by placing on hot plate at 120° C. for 20 min. In situ nanowire suspensions with various compositions were spun on the substrates (2000 rpm, 60 s). Devices were dried under the same conditions as described above for solar cells. Electrical characteristics of the field-effect transistors were measured on a Keithley 4200 semiconductor characterization system (Keithley Instruments Inc. Cleveland, Ohio). The field-effect mobility was calculated from the equation for saturation region. All the measurements were done under dark condition in air.

Transmission electron microscopy (TEM) images were acquired on a Phillips EM420 microscope at 100 kV with objective aperture in to enhance the contrast. P3BT:PC₆₁BM blend films for TEM imaging were prepared from solutions diluted about 10 times by the same ODCB solvent. The samples for TEM acquisition were prepared by dropping a small amount of the diluted P3BT:PC₆₁BM blend solution onto a TEM grid and allowed to dry in a glove box overnight. Measurement of the width (diameter) of the nanowires was made by using ImageJ software (v 1.39, NIH) to analyze the TEM images. Atomic Force Microscopy (AFM) images were measured from the same film as in the solar cell devices by using a Dimension 3100 Scanning Probe Microscope (Veeco Instruments Inc., Woodbury, N.Y.) in standard tapping mode.

UV-Vis absorption spectra were recorded on a Perkin-Elmer model Lambda 900 UV/Vis/near-IR spectrophotometer. The P3BT films for absorption measurements were spin-coated on glass slides whereas P3BT:PC₆₁BM blend films were spin-coated on top of ITO/PEDOT substrates. All blend films were annealed under the same conditions as those of the photovoltaic devices.

### Example 3

### The Effect of Annealing on the Characteristics of Representative Nanowires, Composites, and Related Structures

In this example, the effect of annealing on the characteristics of poly(3-butylthiophene) (P3BT) nanowires and composites, photovoltaic cells, and field effect transistors that include the nanowires are described.

The P3BT nanowires were prepared as described above in Example 1. The P3BT-nw:PC₇₁BM blends for fabricating solar cells or other characterization purpose were made by mixing the P3BT-nw suspension with PC₇₁BM solution at different ratios and stirred for 20 min before spin-coating.

Solar cells were fabricated by first spin-coating a PEDOT buffer layer on top of ITO-coated glass substrates (10 Ω/□, Shanghai B. Tree Tech. Consult Co., Ltd, Shanghai, China) at 3500 rpm for 40 s and dried at 150° C. for 10 min under vacuum. The thickness of PEDOT was around 40 nm. The active blend layer was spin-coated on top of the PEDOT layer from the P3BT-nw:PC₇₁BM blend at a speed of 1000 rpm for 30 s in a glove box and substrate was immediately transferred to a covered Petri dish for drying (aging). After a certain time, the film was either annealed on a 170±10° C. hotplate for 10 min first or directly taken out of the glove box and loaded in a thermal evaporator (BOC Edwards, 306) for the deposition of the cathode. The active layer had a thickness about 80 nm. The cathode consisting of 1.0 nm LiF and 80 nm aluminum layers was sequentially deposited through a shadow mask on top of the active layers in a vacuum of 8×10⁻⁷ Torr. Each substrate contained 5 solar cells with an active area of 3.57 mm². Devices for space-charge limited current (SCLC) hole mobility measurement were fabricated similar to those of solar cells. The main difference is that in order to facilitate hole-only injection and transport, gold electrode was deposited instead of the lithium fluoride (LiF) and aluminum cathode in the solar cells. Film thickness was measured by Alpha-Step 500 profilometer (KLA-Tencor, San Jose, Calif.). Current-voltage characteristics of both solar cells and SCLC devices were measured by using a HP4155A semiconductor parameter analyzer (Yokogawa Hewlett-Packard, Tokyo). The light intensity of 1.5 AM sunlight from a filtered Xe lamp was controlled by using a set of neutral density filters. The SCLC characteristics were measured under dark conditions. All the characterization steps were carried out under ambient laboratory air.

Field-effect transistors were fabricated on heavily-doped (n-type) silicon substrates with thermally grown silicon dioxide (300 nm). Doped silicon acted as common gate electrode and silicon dioxide as gate insulator. Source and drain electrodes were patterned on top of the substrates by using photolithography and thermal evaporation of 2 nm thick chromium and 60 nm thick gold. The bottom-contact/bottom-gate devices had channel width of 800 μm and length of 20 μm. Substrates were cleaned by ultrasonication with acetone and isopropyl alcohol, and purged with argon. Octyltriethoxysilane (OTS-8) monolayer was deposited on the substrates in vacuum dessicator at 60° C. for more than 6 hours, and crosslinked by placing on hot plate at 120° C. for 20 min. Nanowire suspension and nanowires/fullerene blends with different compositions were spun on the substrates (2000 rpm, 60 s). Devices were processed under the same conditions as described above for solar cells. Electrical characteristics of the field-effect transistors were measured on a Keithley 4200 semiconductor characterization system (Keithley Instruments Inc. Cleveland, Ohio). The field-effect mobility was calculated from the equation for saturation region. All the measurements were done under dark condition in air.

The AFM images were acquired by using a Dimension 3100 Scanning Probe Microscope (Veeco Instruments Inc., Woodbury, N.Y.) in standard tapping mode. The films for atomic force microscopy (AFM) imaging of surface morphology were spin-coated on ITO/PEDOT substrates for both pure P3BT-nw and P3BT-nw/fullerene blends.

Transmission electron microscopy (TEM) images were acquired on a Phillips EM420 microscope at 100 kV with objective aperture in to enhance the contrast. P3BT-nw sample for TEM imaging was prepared from nanowires suspension diluted about 10 times by the same ODCB solvent. The samples for TEM acquisition were prepared by dropping a small amount of the diluted P3BT:PC₆₁BM blend solution onto a TEM grid and allowed to dry in a glove box overnight. Measurement of the width (diameter) of the nanowires was made by using ImageJ software (v 1.39, NIH) to analyze the TEM images. Atomic Force Microscopy (AFM) images were measured from the same film as in the solar cell devices by using a Dimension 3100 Scanning Probe Microscope (Veeco Instruments Inc., Woodbury, N.Y.) in standard tapping mode.

UV-Vis absorption spectra were recorded on a Perkin-Elmer model Lambda 900 UV/vis/near-IR spectrophotometer. Both P3BT-nw and P3BT-nw:PC₇₁BM blend films for absorption measurements were spin-coated on top of ITO/PEDOT substrates and measured by using ITO/PEDOT substrate as reference.

### Example 4

### The Preparation and Characterization of Representative Nanowires and Composites, and Photovoltaic Cells that include the Nanowires

In this example, the preparation and characterization of poly(3-pentylthiophene) (P3PT), P3PT nanowires, and composites and photovoltaic cells that include the nanowires are described.

A regioregular poly(3-pentylthiophene) (P3PT) was prepared as follows. The monomer 2,5-dibromopentylthiophene was first reacted with 0.98 equivalent of butylmagnesium chloride in anhydrous THF at room temperature under nitrogen. Then, 1,2-bis(diphenylphosphino)ethane (ligand) and bis(1,5-cyclooctadiene)nickel (0) (catalyst) were added and the mixture was refluxed for 30h. The reaction mixture was cooled to room temperature, the product was precipitated in methanol, collected, and Soxhlet extracted using methanol and hexane as eluents to afford the product as a purple solid. The regioregularity was determined to be 94.3% from ¹H NMR spectra, and the number-average and weight-average molecular weights were 54,000 g/mol and 77,000 g/mol, respectively.

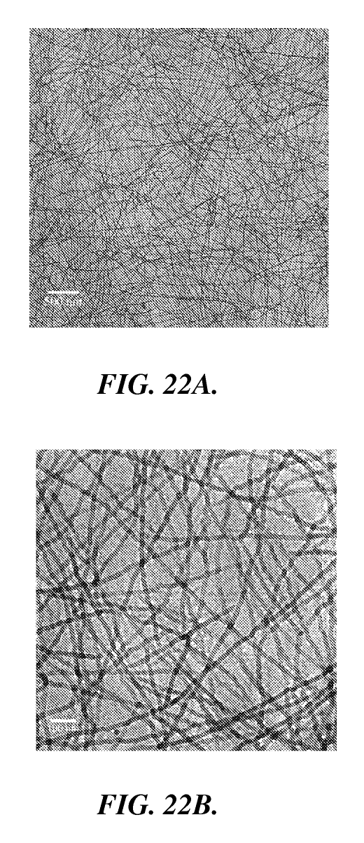

P3PT formed nanowires in ODCB solution as revealed by the TEM image (see FIGS. 22A and 22B). The nanowires were synthesized by dissolving 6 mg P3PT in 1 mL ODCB by heating at 100° C. and stirring for 24 h. The hot solution was filtered through a 0.45 μm PTFE filter and put in a dark environmental for 3 days. A field-effect hole mobility of 0.011 cm²/Vs was measured from a spin coated film of the P3PT nanowires.

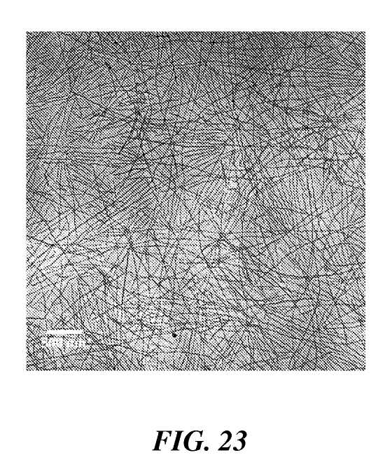

P3PT nanowires were also formed from blends with fullerene (1:1 ratio) (i.e., in-situ formed nanowires), prepared as described in Example 2, as revealed by the TEM image in FIG. 23.

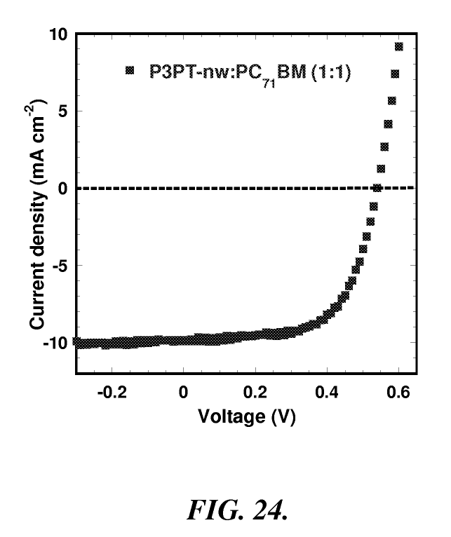

Solar cells, fabricated as described in Examples 1 and 2, using P3PT-nw:PC₆₁BM (1:1) nanowire composites as the active layer showed a power conversion efficiency of 2.62% with J_{SC}=7.19 mA/cm², V_{OV}=0.56 V and FF=0.65. When PC₆₁BM was replaced by PC₇₁BM, a power conversion efficiency of 3.33% with J_{SC}=9.81 mA/cm², V_{OC}=0.54 V and FF=0.63 was achieved due to increased absorption. The J-V curve of P3PT-nw:PC₇₁BM solar cell is shown in FIG. 24.

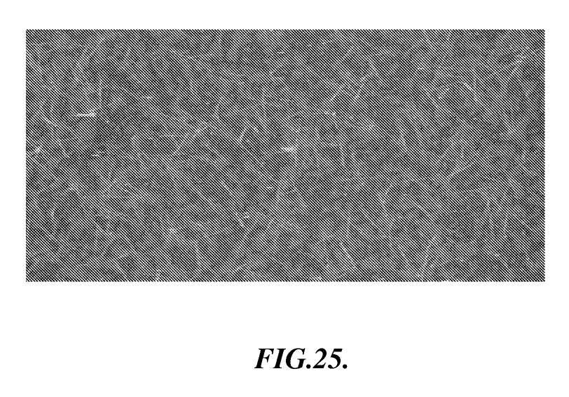

P3PT not only self-assembled to nanowires in solution, but also in thin films spin-coated from solution. FIG. 25 shows the AFM image of P3PT film spin-coated from a 2 mg/ml ODCB solution. The interconnected nanowires can be clearly seen in this image. A high field-effect hole mobility of 0.033 cm²/Vs with the on/off ratio (Iₒₙ/I_{off}) of 10³ was observed in this film.

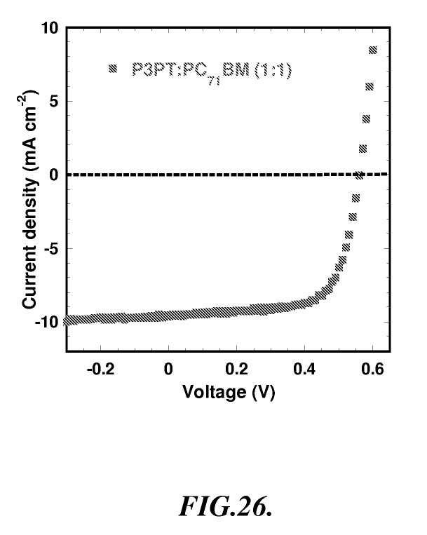

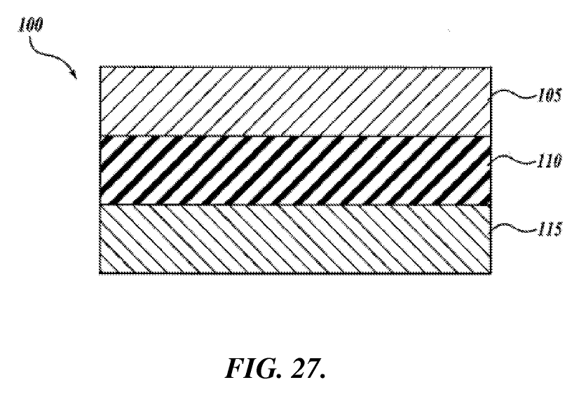

Photovoltaic cells of P3PT:PC₇₁BM (1:1) were tested by spin-coating the active layer from the blend solution. A power conversion efficiency of 3.70% with J_{SC}=9.63 mA/cm², V_{OC}=0.56 V, and FF=0.69 was observed in device with a structure of ITO/PEDOT/P3PT:PC₇₁BM (1:1)/LiF/Al (FIG. 26).

While illustrative embodiments have been illustrated and described, it will be appreciated that various changes can be made therein without departing from the spirit and scope of the invention.

1. A nanowire, comprising a poly(3-pentylthiophene).

2-5. (canceled)

6. A composite, comprising:
(a) one or more poly(3-alkylthiophene) nanowires; and
(b) one or more bulk heterojunction solar cell acceptor compounds.

7. The composite of claim 6, wherein the poly(3-alkylthiophene) nanowire comprises a poly(3-alkylthiophene) selected from the group consisting of poly(3-methylthiophene), poly(3-ethylthiophene), poly(3-propylthiophene), poly(3-butylthiophene), poly(3-pentylthiophene), poly(3-hexylthiophene), poly(3-heptylthiophene), poly(3-octylthiophene), poly(3-nonylthiophene), poly(3-decylthiophene), and mixtures thereof.

8. The composite of claim 6, wherein the acceptor compound is selected from the group consisting of a fullerene or fullerene derivative, an inorganic nanocrystal, and a semiconducting nanoparticle.

9. The composite of claim 6, wherein the acceptor compound is selected from the group consisting of [6,6]-phenyl-C₆₁ butyric acid methyl ester, [6,6]-phenyl-C₇₁ butyric acid methyl ester, and [6,6]-phenyl-C₈₅ butyric acid methyl ester.

10. The composite of claim 6, wherein the ratio of poly(3-alkylthiophene) nanowire to acceptor compound is from about 1:0.2 to about 1:5 (weight ratio).

11. The composite of claim 6 having a thickness of from about 30 to about 500 nm.

12. A method for making a composite, comprising depositing a mixture of one or more poly(3-alkylthiophene) nanowires and one or more bulk heterojunction solar cell acceptor compounds onto a substrate to provide a composite.

13. The method of claim 12, wherein the mixture of the one or more acceptor compounds and the one or more nanowires is prepared by combining a first solution comprising the one or more acceptor compounds in a first solvent with a suspension of the one or more nanowires in a second solvent.

14. The method of claim 12, wherein the mixture of the one or more acceptor compounds and the one or more nanowires is prepared by combining a first solution comprising the one or more acceptor compounds in a first solvent with second solution comprising one or more poly(3-alkylthiophene)s in a second solvent.

15. The method of claim 12, wherein depositing the mixture of one or more poly(3-alkylthiophene) nanowires and one or more bulk heterojunction solar cell acceptor compounds onto a substrate comprises spin coating, drop coating, blade coating, spray coating, or screen printing the mixture.

16-17. (canceled)

18. The method of claim 12, wherein the ratio of acceptor compound to nanowires in the mixture is from about 0.2:1 to about 5:1 (weight ratio).

19. The method of claim 12 further comprising thermal annealing the composite.

20. (canceled)

21. A photovoltaic device, comprising:
(a) a hole-collecting electrode;
(b) a photovoltaic layer comprising one or more poly(3-alkylthiophene) nanowires, and one or more bulk heterojunction solar cell acceptor compounds; and
(c) an electron-collecting electrode.

22-23. (canceled)

24. The device of claim 21 further comprising an electron-transporting or hole-blocking layer intermediate the photovoltaic layer and the electron-collecting electrode.

25-26. (canceled)

27. The device of claim 21 further comprising a hole-transporting layer intermediate the photovoltaic layer and the hole-collecting electrode.

28. The device of claim 21 further comprising a substrate.

29. (canceled)

30. A method for making a photovoltaic device, comprising:
(a) forming a photovoltaic layer on a hole-collecting electrode, wherein the photovoltaic layer comprises one or more poly(3-alkylthiophene) nanowires, and one or more bulk heterojunction solar cell acceptor compounds; and
(b) forming an electron-collecting electrode on the photovoltaic layer.

31. A method for making a photovoltaic device, comprising:
(a) forming a photovoltaic layer on an electron-collecting electrode, wherein the photovoltaic layer comprises one or more poly(3-alkylthiophene) nanowires, and one or more bulk heterojunction solar cell acceptor compounds; and
(b) forming a hole-collecting electrode on the photovoltaic layer.

32. The method of claim 30, wherein forming the photovoltaic layer comprises spin coating, drop coating, blade coating, spray coating, or screen printing a composition comprising one or more poly(3-alkylthiophene nanowires, and one or more bulk heterojunction solar cell acceptor compounds.

33. (canceled)

34. The method of claim 30 further comprising forming a hole-transporting layer.

35. The method of claim 30 further comprising forming an electron-transporting layer.

36. A method for generating an electrical current, comprising exposing the photovoltaic layer of the photovoltaic device of claim 21 to electromagnetic radiation of a wavelength sufficient to generate electrons and holes in the photovoltaic layer.
